(19) United States
(12) Patent Application Publication
(10) Pub. No.: US 2026/0181886 A1
(43) Pub. Date: Jun. 25, 2026

(54) METHOD OF MANUFACTURING SEMICONDUCTOR DEVICE

(71) Applicant: Renesas Electronics Corporation, Tokyo (JP)

(72) Inventor: Akira MITSUIKI, Tokyo (JP)

(21) Appl. No.: 19/368,138

(22) Filed: Oct. 24, 2025

(30) Foreign Application Priority Data
Dec. 19, 2024 (JP) 2024-224408

(51) Int. Cl. H10B 41/35; H10D 64/01

(52) U.S. Cl. CPC H10B 41/35; H10D 64/0112; H10D 64/01354

(57) ABSTRACT

After a silicon oxide film is formed on a main surface of a semiconductor substrate so as to cover a floating gate electrode and a gate electrode, an isotropic etching is performed on the silicon oxide film with a photoresist pattern formed thereon used as an etching mask, and an anisotropic etching is further performed on the silicon oxide film. Accordingly, the silicon oxide film exposed from the photoresist pattern is removed, and a first insulating film made of the silicon oxide film remaining below the photoresist pattern is formed. The first insulating film covers the floating gate electrode. After a metal silicide layer is formed on the gate electrode, a second insulating film made of silicon nitride is formed on the main surface of the semiconductor substrate so as to cover the floating gate electrode, the gate electrode, the metal silicide layer, and the first insulating film.

### CROSS-REFERENCE TO RELATED APPLICATIONS

The disclosure of Japanese Patent Application No. 2024-224408 filed on December 19, 2024 including the specification, drawings and abstract is incorporated herein by reference in its entirety.

### BACKGROUND

The present invention relates to a method of manufacturing a semiconductor device, and is, for example, preferably applicable to a method of manufacturing a semiconductor device having a non-volatile memory.

As a non-volatile memory, a non-volatile memory having a floating gate electrode has been known. In the non-volatile memory having a floating gate electrode, charges are accumulated in the floating gate electrode, thereby allowing information to be stored.

There is disclosed a technique listed below.

Patent Document 1 Japanese Unexamined Patent Application Publication No. 2011-199124

Patent Document 1 discloses a technique related to a non-volatile memory having a floating gate electrode.

### SUMMARY

Enhancement of performance of a semiconductor device including a non-volatile memory with a floating gate electrode has been demanded.

The other purposes and new features of the present invention will become clear from the description of the present specification and the accompanying drawings.

According to one embodiment, a floating gate electrode is formed on a main surface of a semiconductor substrate via a first gate insulating film, and a gate electrode is formed on the main surface of the semiconductor substrate via a second gate insulating film. Then, a first sidewall spacer is formed on a side surface of the floating gate electrode, and a second sidewall spacer is formed on a side surface of the gate electrode. Then, a silicon oxide film is formed on the main surface of the semiconductor substrate so as to cover the floating gate electrode, the gate electrode, the first sidewall spacer, and the second sidewall spacer. Then, after a mask layer is formed on the silicon oxide film, with the mask layer used as an etching mask, an isotropic etching is performed on the silicon oxide film. Then, with the mask layer used as the etching mask, an anisotropic etching is performed on the silicon oxide film. Accordingly, the silicon oxide film exposed from the mask layer is removed, and a first insulating film made of the silicon oxide film which remains below the mask layer is formed. The first insulating film covers the floating gate electrode. Then, after the mask layer is removed, a metal silicide layer is formed on the gate electrode. Then, a silicon nitride film is formed on the main surface of the semiconductor substrate so as to cover the floating gate electrode, the gate electrode, the first sidewall spacer, and the second sidewall spacer. The first insulating film is interposed between the floating gate electrode and the silicon nitride film.

According to one embodiment, it is possible to enhance performance of a semiconductor device.

### BRIEF DESCRIPTION OF THE DRAWINGS

FIG. 1 is a cross-sectional view of main portions of a semiconductor device according to an embodiment.

FIG. 2 is a cross-sectional view of the main portions of the semiconductor device according to the embodiment.

FIG. 3 is a process flow indicating part of a process of manufacturing the semiconductor device according to the embodiment.

FIG. 4 is a cross-sectional view of the main portions of the semiconductor device according to the embodiment, during the manufacturing process.

FIG. 5 is a cross-sectional view of the main portions of the same semiconductor device as shown in FIG. 4, during the manufacturing process.

FIG. 6 is a cross-sectional view of the main portions of the semiconductor device, during the manufacturing process continued from FIG. 4.

FIG. 7 is a cross-sectional view of the main portions of the same semiconductor device as shown in FIG. 6, during the manufacturing process.

FIG. 8 is a cross-sectional view of the main portions of the semiconductor device, during the manufacturing process continued from FIG. 6.

FIG. 9 is a cross-sectional view of the main portions of the same semiconductor device as shown in FIG. 8, during the manufacturing process.

FIG. 10 is a cross-sectional view of the main portions of the semiconductor device, during the manufacturing process continued from FIG. 8.

FIG. 11 is a cross-sectional view of the main portions of the same semiconductor device as shown in FIG. 10, during the manufacturing process.

FIG. 12 is a cross-sectional view of the main portions of the semiconductor device, during the manufacturing process continued from FIG. 10.

FIG. 13 is a cross-sectional view of the main portions of the same semiconductor device as shown in FIG. 12, during the manufacturing process.

FIG. 14 is a cross-sectional view of the main portions of the semiconductor device, during the manufacturing process continued from FIG. 12.

FIG. 15 is a cross-sectional view of the main portions of the same semiconductor device as shown in FIG. 14, during the manufacturing process.

FIG. 16 is a cross-sectional view of the main portions of the semiconductor device, during the manufacturing process continued from FIG. 14.

FIG. 17 is a cross-sectional view of the main portions of the same semiconductor device as shown in FIG. 16, during the manufacturing process.

FIG. 18 is a cross-sectional view of the main portions of the semiconductor device, during the manufacturing process continued from FIG. 16.

FIG. 19 is a cross-sectional view of the main portions of the same semiconductor device as shown in FIG. 18, during the manufacturing process.

FIG. 20 is a cross-sectional view of the main portions of the semiconductor device, during the manufacturing process continued from FIG. 18.

FIG. 21 is a cross-sectional view of the main portions of the same semiconductor device as shown in FIG. 20, during the manufacturing process.

FIG. 22 is a cross-sectional view of the main portions of the semiconductor device, during the manufacturing process continued from FIG. 20.

FIG. 23 is a cross-sectional view of the main portions of the same semiconductor device as shown in FIG. 22, during the manufacturing process.

FIG. 24 is a cross-sectional view of the main portions of the semiconductor device, during the manufacturing process continued from FIG. 22.

FIG. 25 is a cross-sectional view of the main portions of the same semiconductor device as shown in FIG. 24, during the manufacturing process.

FIG. 26 is a cross-sectional view of the main portions of the semiconductor device, during the manufacturing process continued from FIG. 24.

FIG. 27 is a cross-sectional view of the main portions of the same semiconductor device as shown in FIG. 26, during the manufacturing process.

FIG. 28 is a cross-sectional view of the main portions of the semiconductor device, during the manufacturing process continued from FIG. 26.

FIG. 29 is a cross-sectional view of the main portions of the same semiconductor device as shown in FIG. 28, during the manufacturing process.

FIG. 30 is a cross-sectional view of the main portions of the semiconductor device, during the manufacturing process continued from FIG. 28.

FIG. 31 is a cross-sectional view of the main portions of the same semiconductor device as shown in FIG. 30, during the manufacturing process.

FIG. 32 is a cross-sectional view of the main portions of the semiconductor device, during the manufacturing process continued from FIG. 30.

FIG. 33 is a cross-sectional view of the main portions of the same semiconductor device as shown in FIG. 32, during the manufacturing process.

FIG. 34 is a process flow indicating part of a process of manufacturing a semiconductor device according to a first study example.

FIG. 35 is a cross-sectional view of main portions of the semiconductor device according to the first study example, during the manufacturing process.

FIG. 36 is a cross-sectional view of the main portions of the same semiconductor device as shown in FIG. 35, during the manufacturing process.

FIG. 37 is a cross-sectional view of the main portions of the semiconductor device, during the manufacturing process continued from FIG. 35.

FIG. 38 is a cross-sectional view of the main portions of the same semiconductor device as shown in FIG. 37, during the manufacturing process.

FIG. 39 is a cross-sectional view of the main portions of the semiconductor device, during the manufacturing process continued from FIG. 37.

FIG. 40 is a cross-sectional view of main portions of a semiconductor device according to a second study example, during a manufacturing process.

FIG. 41 is a cross-sectional view of the main portions of the same semiconductor device as shown in FIG. 40, during the manufacturing process.

FIG. 42 is a cross-sectional view of the main portions of the semiconductor device, during the manufacturing process continued from FIG. 40.

FIG. 43 is a cross-sectional view of the main portions of the same semiconductor device as shown in FIG. 42, during the manufacturing process.

FIG. 44 is a cross-sectional view of the main portions of the semiconductor device, during the manufacturing process continued from FIG. 42.

FIG. 45 is a cross-sectional view of the main portions of the same semiconductor device as that of FIG. 44, during the manufacturing process.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including the number of pieces, numerical values, amount, range, and the like), the number of elements is not limited to a specific number unless otherwise stated, except a case where the number is apparently limited to a specific number in principle, and the like. The number larger or smaller than the specific number is also applicable. Further, in the embodiments described below, it goes without saying that the components (including element steps and the like) are not always indispensable unless otherwise stated, except a case where the components are apparently indispensable in principle, and the like. Similarly, in the embodiments described below, when the shape of the components or the like, positional relation thereof, and the like are mentioned, the substantially approximate and similar shapes and the like are included therein unless otherwise stated, except a case where it is conceivable that they are apparently excluded in principle, and the like. The same goes for the numerical value and the range described above.

Hereinafter, embodiments will be described in detail with reference to the accompanying drawings. Note that components having the same function are denoted by the same reference symbols throughout the drawings for describing the embodiments, and the repetitive description thereof is omitted. In addition, the description of the same or similar portions is not repeated in principle unless particularly required in the following embodiments.

In addition, in some drawings used in the embodiments, hatching may be omitted even in a cross-sectional view so as to make the drawings easy to see. Also, hatching may be used even in a plan view so as to make the drawings easy to see.

In addition, a plan view corresponds to viewing an object from a plane substantially parallel to a main surface or a back surface of a semiconductor substrate SB. In addition, a bottom surface and a lower surface have the same meaning.

In addition, in the present application, a MOSFET (Metal Oxide Semiconductor Field Effect Transistor) includes not only a MOSFET using an oxide film as a gate insulating film, but also a MOSFET using an insulating film other than the oxide film as the gate insulating film.

### EMBODIMENT

### REGARDING STRUCTURE OF SEMICONDUCTOR DEVICE

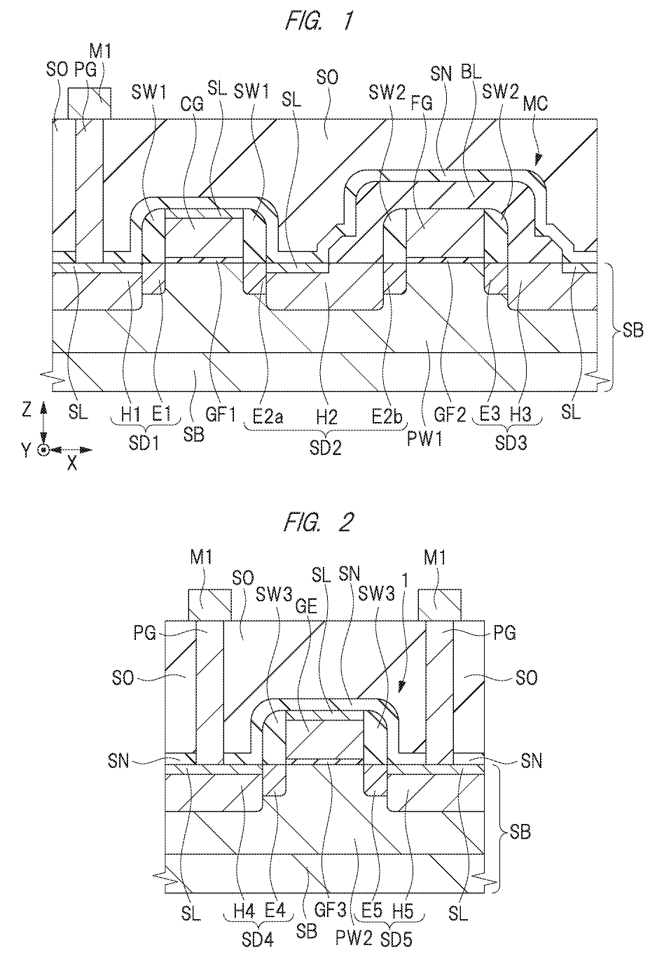

With reference to FIG. 1 and FIG. 2, a semiconductor device according to an embodiment will be described. In FIG. 1, a cross-sectional view of main portions of a memory formation region in which a memory element (storage element) MC constituting a non-volatile memory (non-volatile storage element or flash memory) is formed is illustrated. FIG. 1 illustrates an X direction, a Y direction, and a Z direction. The X direction and the Y direction are substantially parallel to the main surface of the semiconductor substrate SB, and the Z direction is substantially vertical to the main surface of the semiconductor substrate SB. The X direction, the Y direction, and the Z direction are perpendicular to one another. The cross-sectional view illustrated in FIG. 1 is parallel to the X direction and the Z direction and is vertical to the Y direction. In FIG. 2, a cross-sectional view of main portions of a peripheral circuit region in which peripheral circuits are formed is illustrated. The peripheral circuits are circuits other than the non-volatile memory and include, for example, a processor such as a central processing circuit (CPU), a control circuit, a sense amplifier, a column decoder, a row decoder, and an input/output circuit.

As illustrated in FIG. 1, the semiconductor device according to the embodiment includes the semiconductor substrate SB, a p-type well PW1, a control gate electrode CG, a floating gate electrode FG, a gate insulating film GF1, a gate insulating film GF2, an n-type semiconductor region SD1, an n-type semiconductor region SD2, an n-type semiconductor region SD3, sidewall spacers SW1, sidewall spacers SW2, and an insulating film BL. As illustrated in FIG. 2, the semiconductor device according to the embodiment further includes a p-type well PW2, a gate electrode GE, a gate insulating film GF3, sidewall spacers SW3, an n-type semiconductor region SD4, and an n-type semiconductor region SD5. As illustrated in FIG. 1 and FIG. 2, the semiconductor device according to the embodiment further includes a metal silicide layer SL, an insulating film SN, an insulating film SO, plugs PG, and wires M1.

With reference to FIG. 1, the memory formation region will be described.

The semiconductor substrate SB is made of, for example, p-type single-crystal silicon. The semiconductor substrate SB has the main surface and the back surface opposite to the main surface.

The p-type well PW1, the n-type semiconductor region SD1, the n-type semiconductor region SD2, and the n-type semiconductor region SD3 are formed in the semiconductor substrate SB.

The control gate electrode CG is formed on the main surface of the semiconductor substrate SB (on the p-type well PW1) via the gate insulating film GF1. Hence, the gate insulating film GF1 is interposed between the control gate electrode CG and the semiconductor substrate SB. A gate width direction of the control gate electrode CG is the Y direction, and a gate length direction of the control gate electrode CG is the X direction.

The floating gate electrode (floating gate electrode) FG is formed on the main surface of the semiconductor substrate SB (on the p-type well PW1) via the gate insulating film GF2. Hence, the gate insulating film GF2 is interposed between the floating gate electrode FG and the semiconductor substrate SB. A gate width direction of the floating gate electrode FG is the Y direction, and a gate length direction of the floating gate electrode FG is the X direction. The control gate electrode CG and the floating gate electrode FG are spaced apart from each other.

The sidewall spacer SW1 is formed on a side surface (side wall) of the control gate electrode CG, as a side wall insulating film. The sidewall spacer SW2 is formed on a side surface (side wall) of the floating gate electrode FG as a side wall insulating film.

The control gate electrode CG and the floating gate electrode FG are adjacent to each other in the X direction. In the X direction, the n-type semiconductor region SD2 is located between the n-type semiconductor region SD1 and the n-type semiconductor region SD3. The control gate electrode CG and the floating gate electrode FG are located on a portion of the semiconductor substrate SB between the n-type semiconductor region SD1 and the n-type semiconductor region SD3. Specifically, the control gate electrode CG is located on a portion of the semiconductor substrate SB between the n-type semiconductor region SD1 and the n-type semiconductor region SD2. In addition, the floating gate electrode FG is located on a portion of the semiconductor substrate SB between the n-type semiconductor region SD2 and the n-type semiconductor region SD3.

The n-type semiconductor region SD1, the n-type semiconductor region SD2, and the n-type semiconductor region SD3 are formed in the p-type well PW1. The n-type semiconductor region SD1 is a semiconductor region being for source or drain. The n-type semiconductor region SD1 includes an n-type semiconductor region E1 and an n-type semiconductor region H1. An n-type impurity concentration of the n-type semiconductor region H1 is higher than an n-type impurity concentration of the n-type semiconductor region E1. Accordingly, the n-type semiconductor region SD1 has a lightly doped drain (LDD) structure. The n-type semiconductor region E1 is located below the sidewall spacer SW1. In plan view, the n-type semiconductor region E1 is located between the n-type semiconductor region H1 and the control gate electrode CG.

The n-type semiconductor region SD2 is a semiconductor region being for source or drain. The n-type semiconductor region SD2 includes an n-type semiconductor region E2a, an n-type semiconductor region E2b, and an n-type semiconductor region H2. An n-type impurity concentration of the n-type semiconductor region H2 is higher than an n-type impurity concentration of the n-type semiconductor region E2a and an n-type impurity concentration of the n-type semiconductor region E2b. Accordingly, the n-type semiconductor region SD2 has the LDD structure. The n-type semiconductor region E2a is located below the sidewall spacer SW1, and the n-type semiconductor region E2b is located below the sidewall spacer SW2. In plan view, the n-type semiconductor region E2a is located between the n-type semiconductor region H2 and the control gate electrode CG, and the n-type semiconductor region E2b is located between the n-type semiconductor region H2 and the floating gate electrode FG.

The n-type semiconductor region SD3 is a semiconductor region being for source or drain. The n-type semiconductor region SD3 includes an n-type semiconductor region E3 and an n-type semiconductor region H3. An n-type impurity concentration of the n-type semiconductor region H3 is higher than an n-type impurity concentration of the n-type semiconductor region E3. Accordingly, the n-type semiconductor region SD3 has an LDD structure. The n-type semiconductor region E3 is located below the sidewall spacer SW2. In plan view, the n-type semiconductor region E3 is located between the n-type semiconductor region H3 and the floating gate electrode FG.

The metal silicide layer SL is formed on each of an upper surface of the n-type semiconductor region H1, an upper surface of the n-type semiconductor region H2, an upper surface of the n-type semiconductor region H3, and an upper surface of the control gate electrode CG. The metal silicide layer SL is not formed on the floating gate electrode FG.

The insulating film (silicon oxide film) BL is formed so as to cover the floating gate electrode FG and the sidewall spacers SW2. An entire upper surface of the floating gate electrode FG is covered with the insulating film BL. In plan view, the floating gate electrode FG lies inside the insulating film BL. The control gate electrode CG is not covered with the insulating film BL. That is, in plan view, the control gate electrode CG does not overlap with the insulating film BL. The insulating film BL is made of silicon oxide.

Of both ends of the insulating film BL in the X direction, one end thereof is located on the n-type semiconductor region H2, and the other end thereof is located on the n-type semiconductor region H3. Hence, a portion of the n-type semiconductor region H2 is covered with the insulating film BL, and the remaining portion of the n-type semiconductor region H2 is not covered with the insulating film BL and is exposed from the insulating film BL. The metal silicide layer SL is formed on the remaining portion of the n-type semiconductor region H2 that is exposed from the insulating film BL. The metal silicide layer SL is not formed on the portion of the n-type semiconductor region H2 that is covered with the insulating film BL.

A portion of the n-type semiconductor region H3 is covered with the insulating film BL, and the remaining portion of the n-type semiconductor region H3 is not covered with the insulating film BL and is exposed from the insulating film BL. The metal silicide layer SL is formed on the remaining portion of the n-type semiconductor region H3 that is exposed from the insulating film BL. The metal silicide layer SL is not formed on the portion of the n-type semiconductor region H3 that is covered with the insulating film BL.

With reference to FIG. 2, the peripheral circuit region will be described.

As illustrated in FIG. 2, the p-type well PW2 is formed in the semiconductor substrate SB, and the n-type semiconductor region SD4 and the n-type semiconductor region SD5 are formed in the p-type well PW2. In plan view, the p-type well PW2 and the p-type well PW1 are spaced apart from each other.

The gate electrode GE is formed on the main surface of the semiconductor substrate SB (on the p-type well PW2) via the gate insulating film GF3. The gate electrode GE is a gate electrode of a MOSFET1 for the peripheral circuits. The sidewall spacer SW3 is formed on a side surface (side wall) of the gate electrode GE, as a side wall insulating film.

Each of the n-type semiconductor region SD4 and the n-type semiconductor region SD5 is a semiconductor region for the MOSFET1, the semiconductor region being for source or drain. One of the n-type semiconductor region SD4 and the n-type semiconductor region SD5 functions as the source region of the MOSFET1, and the other of the n-type semiconductor region SD4 and the n-type semiconductor region SD5 functions as the drain region of the MOSFET1. In plan view, the gate electrode GE is located between the n-type semiconductor region SD4 and the n-type semiconductor region SD5.

The n-type semiconductor region SD4 includes an n-type semiconductor region E4 and an n-type semiconductor region H4. An n-type impurity concentration of the n-type semiconductor region H4 is higher than an n-type impurity concentration of the n-type semiconductor region E4. The n-type semiconductor region SD5 includes an n-type semiconductor region E5 and an n-type semiconductor region H5. An n-type impurity concentration of the n-type semiconductor region H5 is higher than an n-type impurity concentration of the n-type semiconductor region E5. Hence, each of the n-type semiconductor region SD4 and the n-type semiconductor region SD5 has an LDD structure. The n-type semiconductor region E4 and the n-type semiconductor region E5 are located below the sidewall spacers SW3. In plan view, the n-type semiconductor region E4 is located between the n-type semiconductor region H4 and the gate electrode GE, and the n-type semiconductor region E5 is located between the n-type semiconductor region H5 and the gate electrode GE. The metal silicide layer SL is formed on each of the gate electrode GE, the n-type semiconductor region H4, and the n-type semiconductor region H5. An element corresponding to the insulating film BL (see FIG. 1) is not formed on the gate electrode GE, the n-type semiconductor region H4, and the n-type semiconductor region H5.

With reference to FIG. 1 and FIG. 2, structures of the insulating film SN and above the insulating film SN will be described.

The insulating film (silicon nitride film) SN is formed on the main surface of the semiconductor substrate SB so as to cover the control gate electrode CG, the floating gate electrode FG, the gate electrode GE, the sidewall spacers SW1, the sidewall spacers SW2, the sidewall spacers SW3, the metal silicide layer SL, and the insulating film BL. The insulating film SO is formed on the insulating film SN.

The insulating film SN is made of silicon nitride. A thickness of the insulating film SN is smaller than a thickness of the insulating film SO. The insulating film SO is made of a material different from the insulating film SN and preferably is made of silicon oxide. As the insulating film SO, a low dielectric constant film (Low-k film) having a dielectric constant lower than a dielectric constant of silicon oxide can also be used. A layered film including the insulating film SN and the insulating film SO can function as an interlayer insulating film.

The insulating film BL is interposed between the floating gate electrode FG and the insulating film SN. Hence, the floating gate electrode FG is not in contact with the insulating film SN. The metal silicide layer SL on the control gate electrode CG is in contact with the insulating film SN. The metal silicide layer SL on the gate electrode GE is in contact with the insulating film SN.

A conductive plug PG is formed in a contact hole penetrating the insulating film SO and the insulating film SN. The wires M1 are formed on the insulating film SO. An upper surface of the plug PG is in contact with the wire M1.

The plug PG is disposed above each of the n-type semiconductor region H1, the n-type semiconductor region H3, the n-type semiconductor region H4, the n-type semiconductor region H5, the control gate electrode CG, and the gate electrode GE. In FIG. 1 and FIG. 2, the plug PG disposed above the n-type semiconductor region H1, the plug PG disposed above the n-type semiconductor region H4, and the plug PG disposed above the n-type semiconductor region H5 are illustrated. Since the plug PG is not disposed above the floating gate electrode FG, an electric potential of the floating gate electrode FG is a floating potential.

Illustration and description of a structure above the insulating film SO and the wire M1 will be omitted.

The memory element (storage element, or a memory cell) MC serving as the non-volatile memory includes a control transistor (selection transistor) having the control gate electrode CG and a memory transistor (storage transistor) having the floating gate electrode FG. The control transistor and the memory transistor are connected in series. The n-type semiconductor region SD1 functions as a drain region of the control transistor, the n-type semiconductor region SD3 functions as a source region of the memory transistor, and the n-type semiconductor region SD2 functions as both a source region of the control transistor and a drain region of the memory transistor. Alternatively, the n-type semiconductor region SD1 functions as the source region of the control transistor, the n-type semiconductor region SD3 functions as the drain region of the memory transistor, and the n-type semiconductor region SD2 functions as both the drain region of the control transistor and the source region of the memory transistor. The floating gate electrode FG functions as a charge accumulation layer. Due to accumulation or retention of charges in the floating gate electrode FG, information can be stored in the memory element MC.

At a time of a writing operation for the memory element MC, charges (electrons in this case) are injected from the semiconductor substrate SB to the floating gate electrode FG. At a time of an erase operation for the memory element MC, charges (electrons in this case) accumulated in the floating gate electrode FG are caused to move in the semiconductor substrate SB. A threshold voltage of the memory transistor is different between a state in which the charges (electrons in this case) are accumulated in the floating gate electrode FG and a state in which the charges (electrons in this case) are not accumulated in the floating gate electrode FG, so that information stored in the memory element MC can be read out due to the difference of the threshold voltage of the memory transistor.

In addition, in FIG. 1, a single memory element MC is illustrated. In practice, a plurality of memory elements MC are formed in an array on the main surface of the semiconductor substrate SB.

A case in which both the control transistor and the memory transistor are n-channel MOSFETs has been described. A case in which both the control transistor and the memory transistor are p-channel MOSFETs can also be possible.

A case in which the MOSFET1 for the peripheral circuits is the n-channel MOSFET has been described. A case in which the MOSFET1 for the peripheral circuits is the p-channel MOSFET can also be possible. The peripheral circuits can also have both the n-channel MOSFET and the p-channel MOSFET.

### REGARDING MANUFACTURING PROCESS OF SEMICONDUCTOR DEVICE

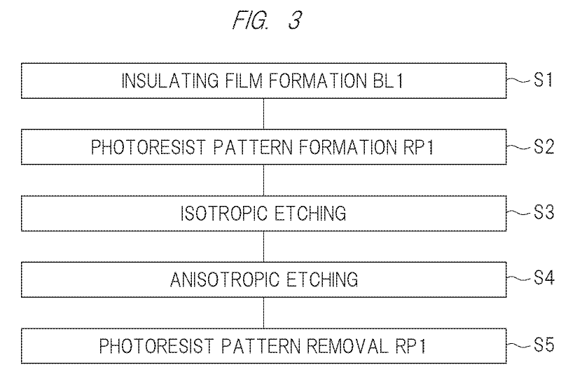

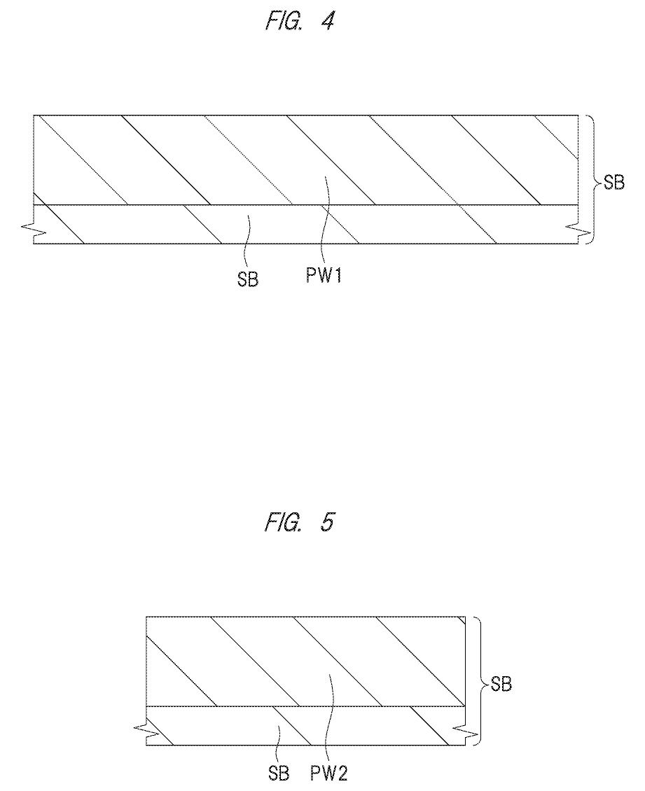

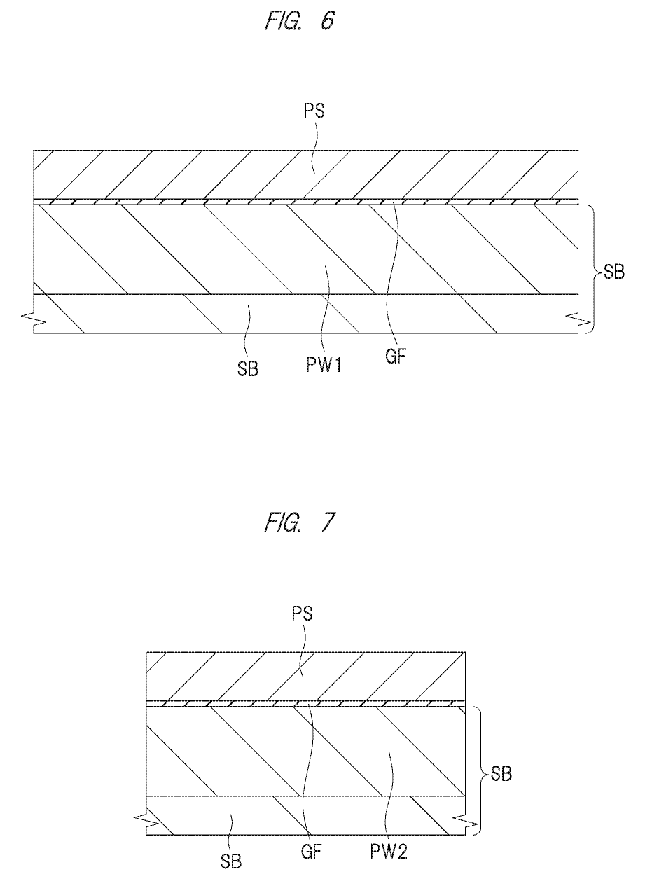

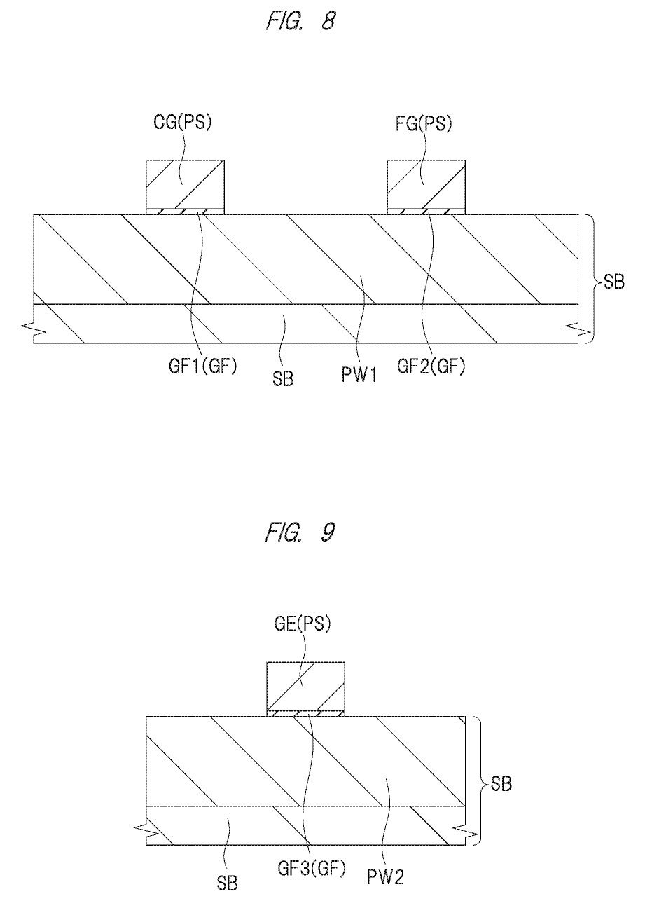

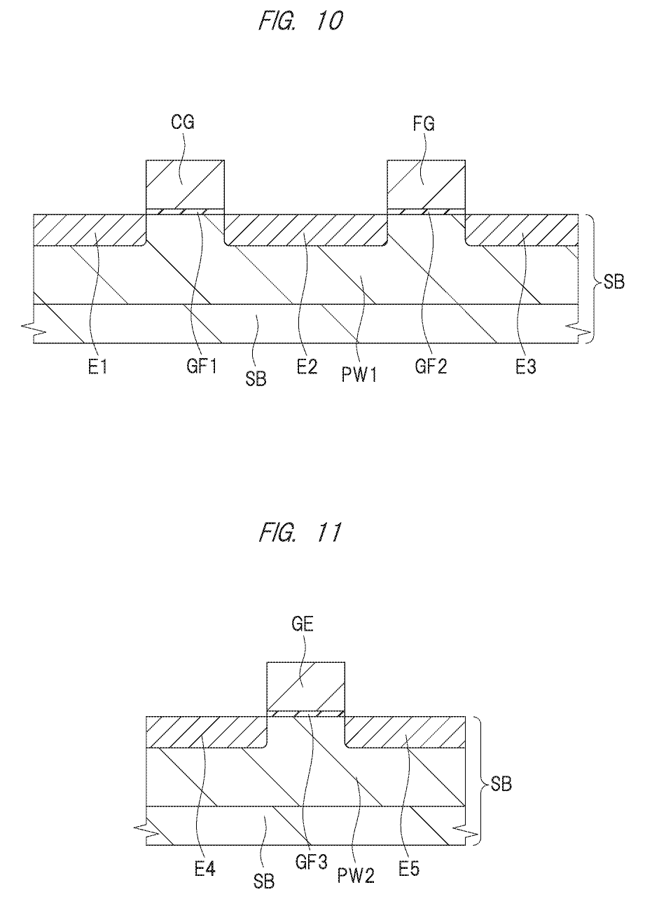

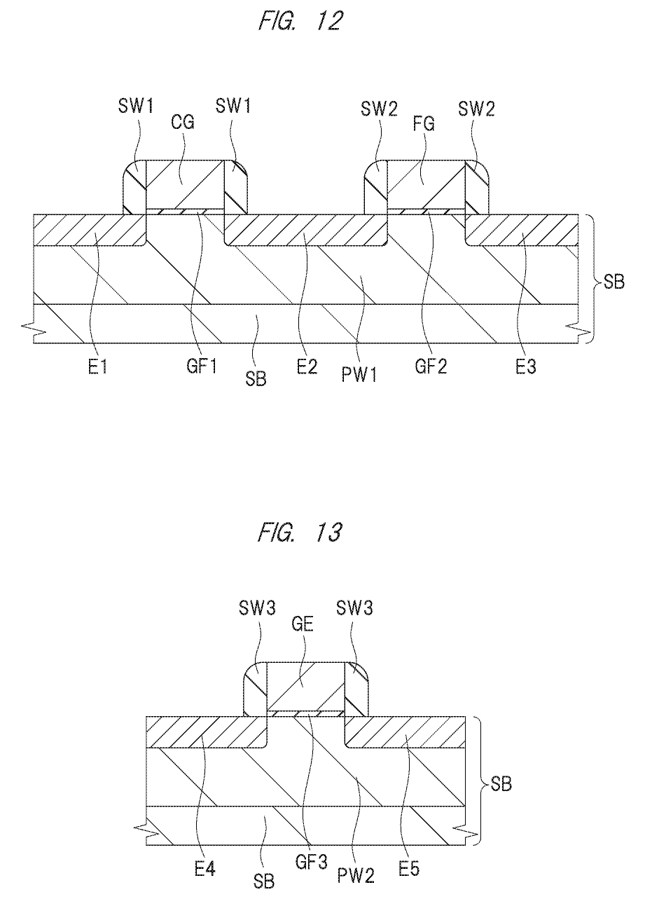

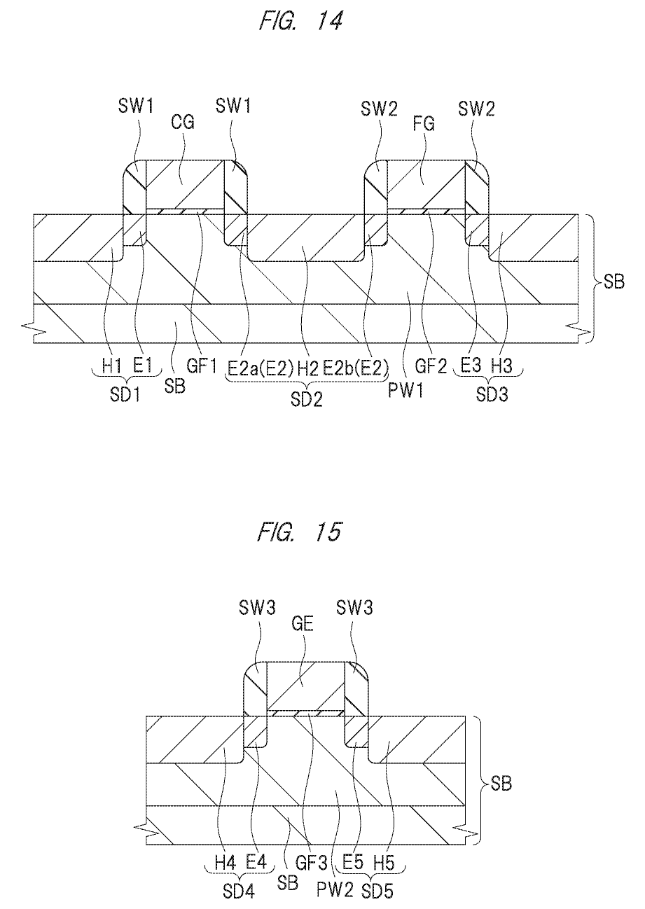

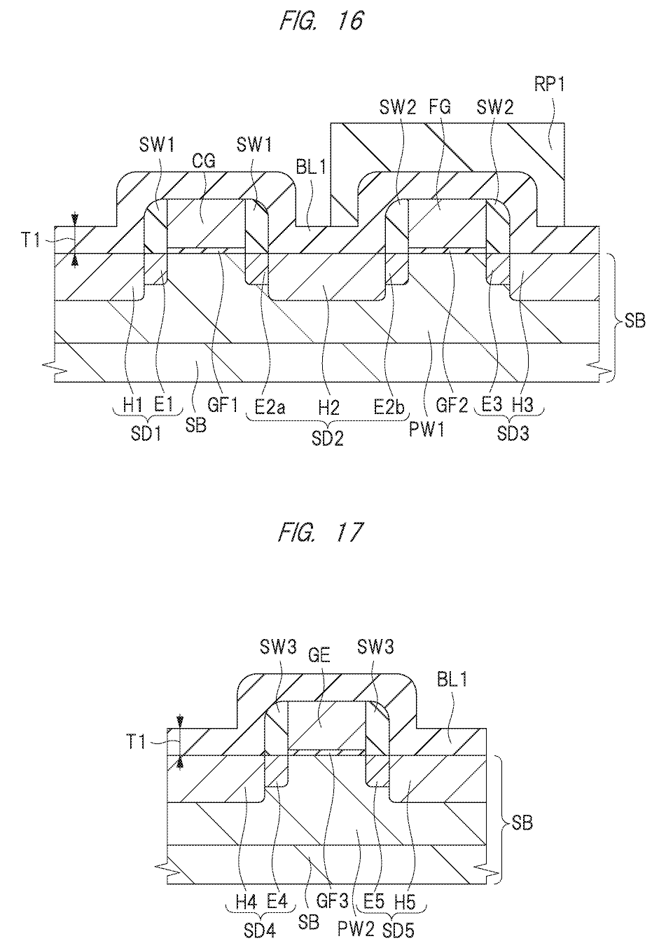

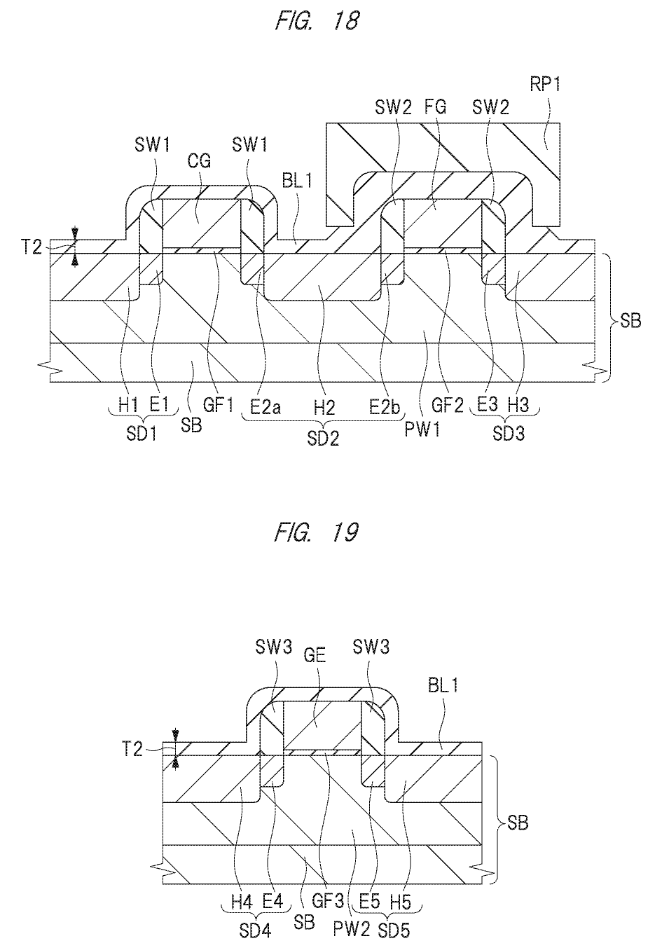

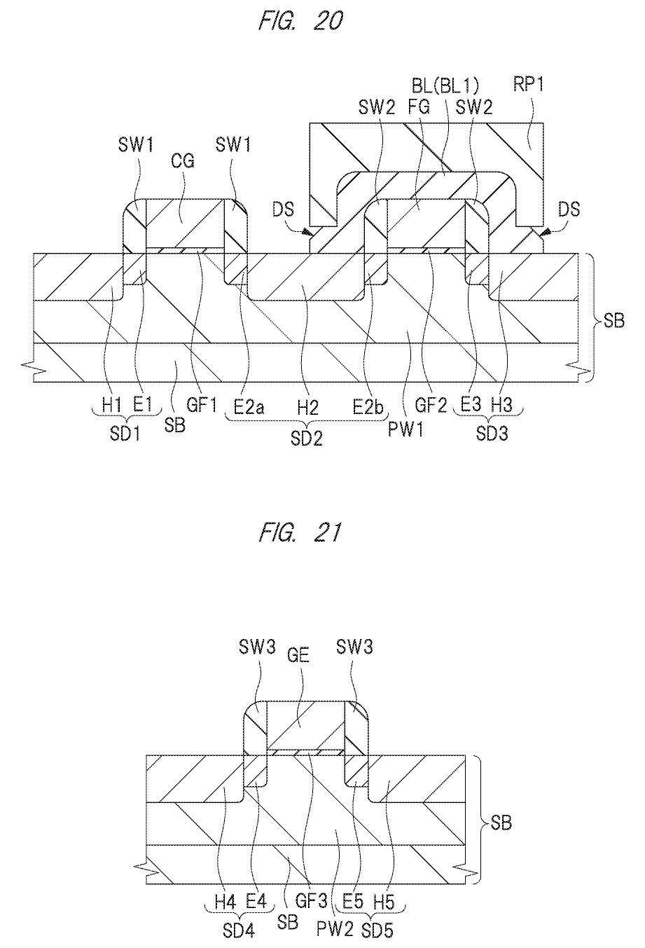

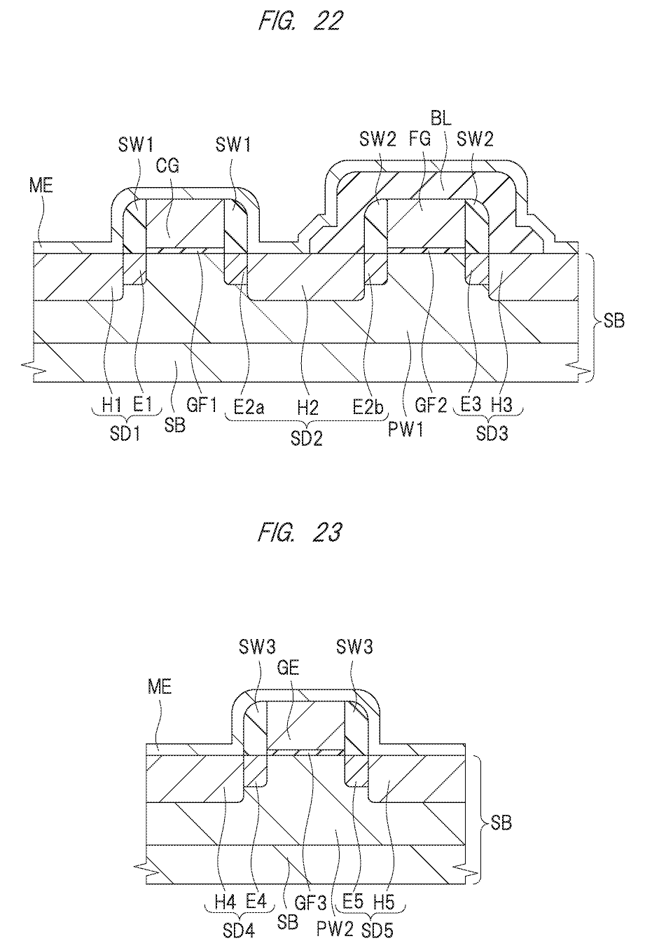

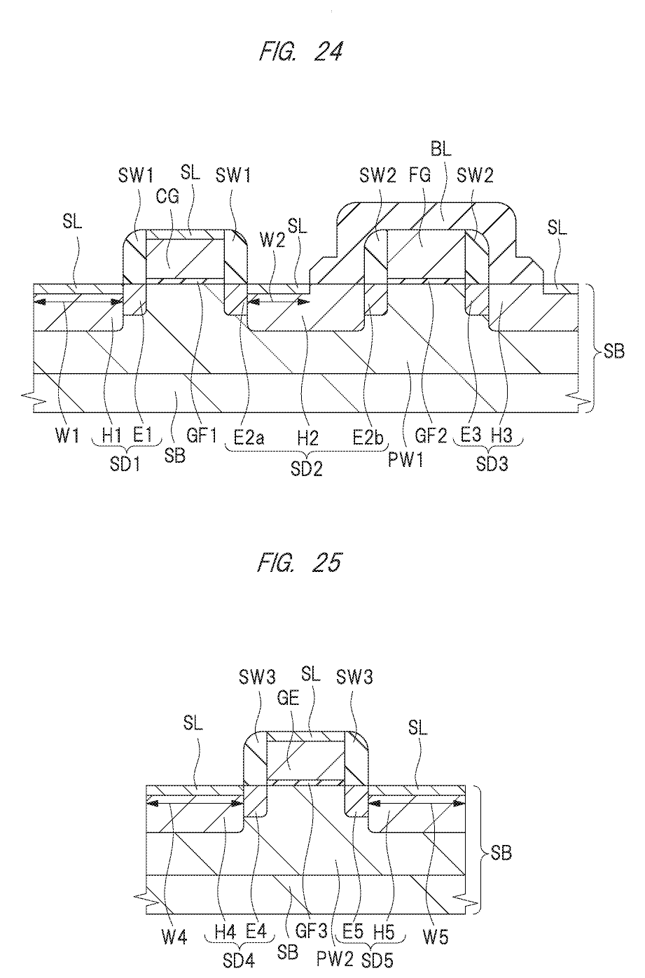

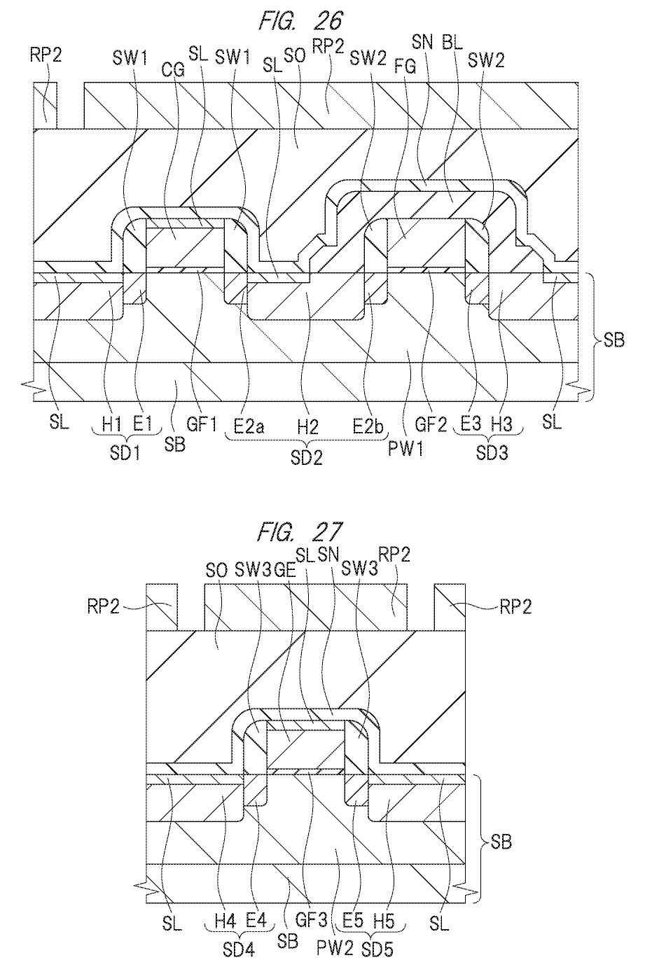

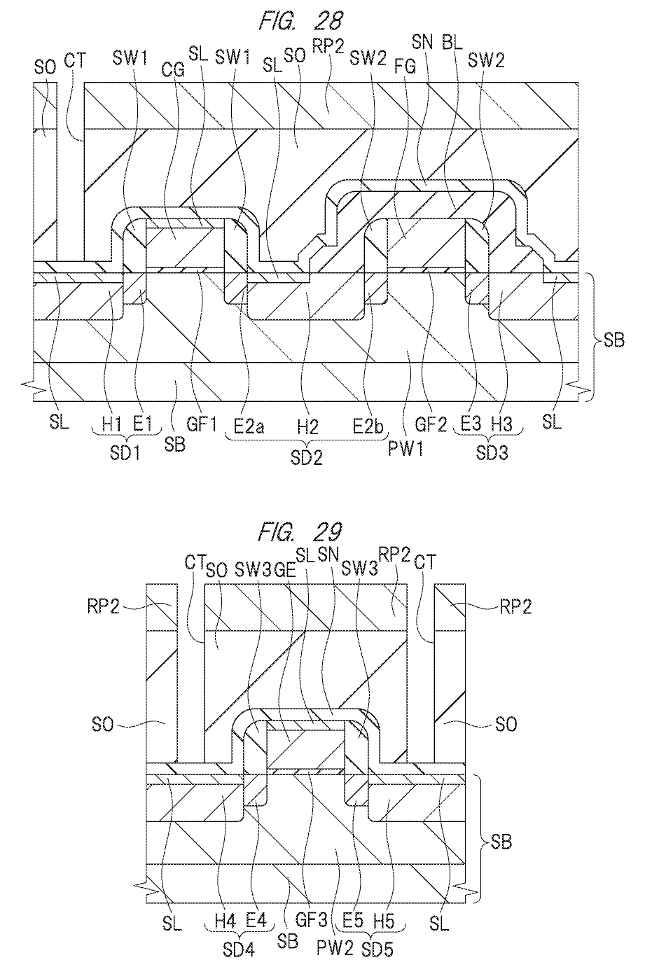

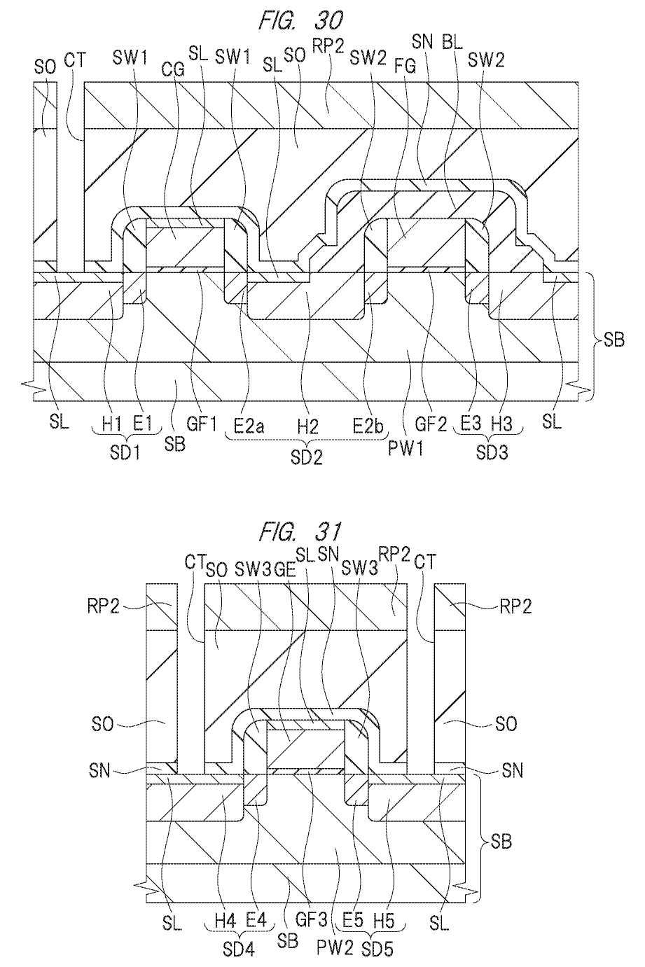

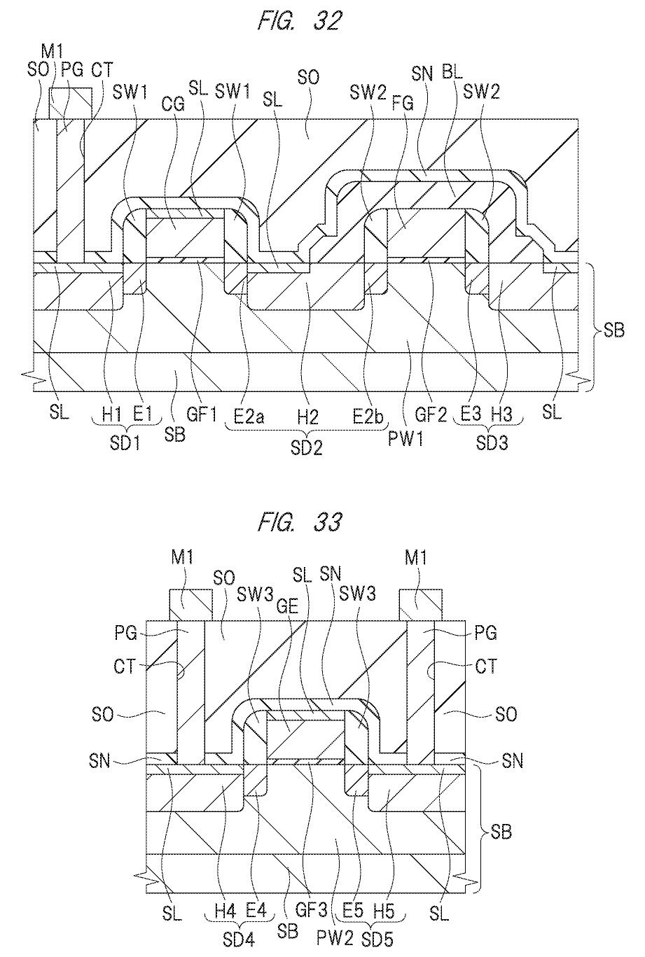

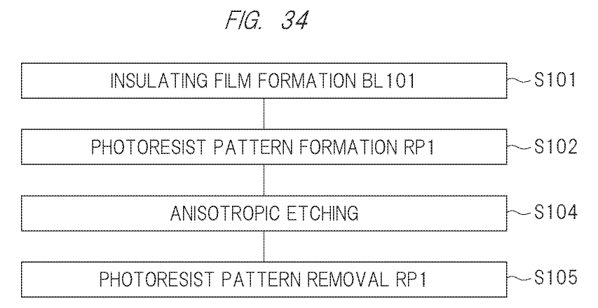

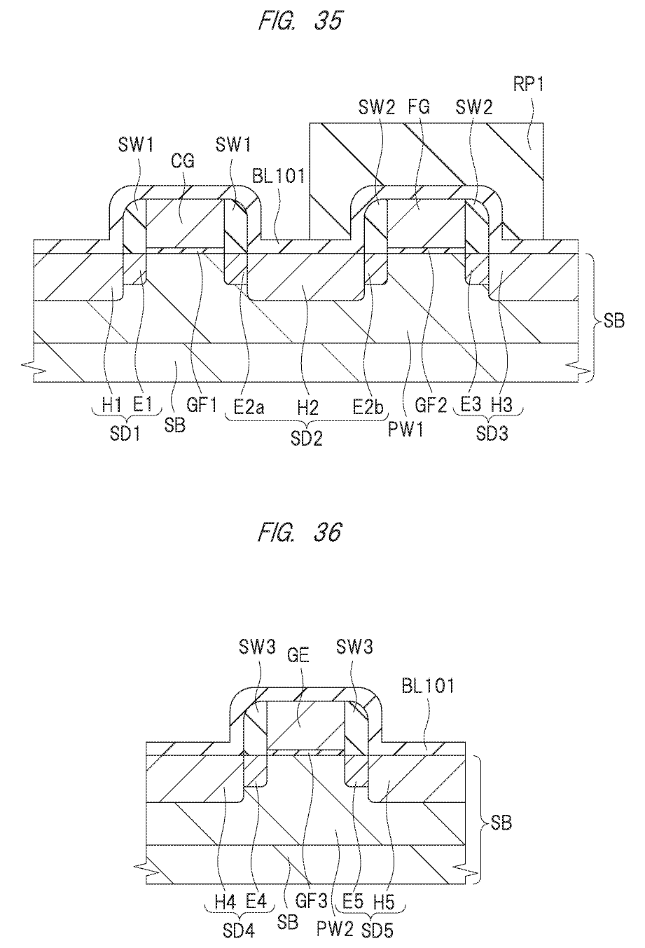

With reference to FIG. 3 through FIG. 35, a method of manufacturing a semiconductor device according to the present embodiment will be described. FIG. 3 is a process flow indicating a formation step for the insulating film BL. FIG. 4, FIG. 6, FIG. 8, FIG. 10, FIG. 12, FIG. 14, FIG. 16, FIG. 18, FIG. 20, FIG. 22, FIG. 24, FIG. 26, FIG. 28, FIG. 30, FIG. 32, and FIG. 34 each indicate a cross section corresponding to FIG. 1. FIG. 5, FIG. 7, FIG. 9, FIG. 11, FIG. 13, FIG. 15, FIG. 17, FIG. 19, FIG. 21, FIG. 23, FIG. 25, FIG. 27, FIG. 29, FIG. 31, FIG. 33, and FIG. 35 each indicate a cross section corresponding to FIG. 2. In this case, a case in which the memory element MC is formed in the memory formation region and the n-channel MOSFET1 is formed in the peripheral circuit region will be described. In place of the n-channel MOSFET1, the p-channel MOSFET may be formed, or both the n-channel MOSFET1 and the p-channel MOSFET can also be formed.

As illustrated in FIG. 4 and FIG. 5, the semiconductor substrate (semiconductor wafer) SB made of p-type single-crystal silicon and the like is provided (prepared).

Next, on the main surface of the semiconductor substrate SB, an element isolation region (not illustrated) defining an active region is formed by the STI (Shallow Trench Isolation).

Next, the p-type well PW1 and the p-type well PW2 are formed in the semiconductor substrate SB by ion implantation. The p-type well PW1 and the p-type well PW2 are spaced apart from each other, in plan view. The p-type well PW1 is formed from the main surface of the semiconductor substrate SB to a predetermined depth in the memory formation region (see FIG. 4). The p-type well PW2 is formed from the main surface of the semiconductor substrate SB to a predetermined depth in the peripheral circuit region (see FIG. 5).

Next, as illustrated in FIG. 6 and FIG. 7, the insulating film GF is formed on the main surface (front surfaces of the p-type well PW1 and the p-type well PW2) of the semiconductor substrate SB. The insulating film GF is made of a silicon oxide film and the like, and can be formed by the thermal oxidation method or the like.

Next, on the main surface of the semiconductor substrate SB, that is, on the insulating film GF, the silicon film PS is formed as a conductive film. The silicon film PS is made of a polysilicon film, and can be formed by the chemical vapor deposition (CVD).

Next, as illustrated in FIG. 8 and FIG. 9, through photolithography and dry etching, the silicon film PS is patterned to form the control gate electrode CG, the floating gate electrode FG, and the gate electrode GE. The control gate electrode CG, the floating gate electrode FG, and the gate electrode GE is made of the silicon film PS having been subjected to patterning, and are formed on the main surface of the semiconductor substrate SB via the insulating film GF. The control gate electrode CG, the floating gate electrode FG, and the gate electrode GE are spaced apart from one another.

The insulating film GF remaining below the control gate electrode CG is the gate insulating film GF1, the insulating film GF remaining below the floating gate electrode FG is the gate insulating film GF2, and the insulating film GF remaining below the gate electrode GE is the gate insulating film GF3. The control gate electrode CG is formed on the p-type well PW1 via the gate insulating film GF1. The floating gate electrode FG is formed on the p-type well PW1 via the gate insulating film GF2. The gate electrode GE is formed on the p-type well PW2 via the gate insulating film GF3.

Next, as illustrated in FIG. 10 and FIG. 11, with use of the ion implantation, in the semiconductor substrate SB, the n-type semiconductor region E1, the n-type semiconductor region E2, the n-type semiconductor region E3, the n-type semiconductor region E4, and the n-type semiconductor region E5 are formed.

The n-type semiconductor region E1, the n-type semiconductor region E2, and the n-type semiconductor region E3 are formed in the p-type well PW1 (see FIG. 10). The n-type semiconductor region E4 and the n-type semiconductor region E5 are formed in the p-type well PW2 (see FIG. 11). The control gate electrode CG, the floating gate electrode FG, and the gate electrode GE can each function as a mask for preventing ion implantation.

Accordingly, the n-type semiconductor region E4 is formed in such a manner as to be self-aligned with one of the side surfaces of the gate electrode GE in the p-type well PW2, and the n-type semiconductor region E5 is formed in such a manner as to be self-aligned with the other of the side surfaces of the gate electrode GE in the p-type well PW2. The n-type semiconductor region E1 is formed in such a manner as to be self-aligned with one of the side surfaces of the control gate electrode CG in the p-type well PW1. The n-type semiconductor region E3 is formed in such a manner as to be self-aligned with one of the side surfaces of the floating gate electrode FG in the p-type well PW1. The n-type semiconductor region E2 is formed in such a manner as to be self-aligned with the other of the side surfaces of the control gate electrode CG and with the other of the side surfaces of the floating gate electrode FG in the p-type well PW1. In plan view, the n-type semiconductor region E2 is formed between the control gate electrode CG and the floating gate electrode FG.

Next, as illustrated in FIG. 12 and FIG. 13, the sidewall spacers SW1, the sidewall spacers SW2, and the sidewall spacers SW3 are formed. The sidewall spacers SW1 are formed on the side surfaces (side walls) of the control gate electrode CG. The sidewall spacers SW2 are formed on the side surfaces (side walls) of the floating gate electrode FG. The sidewall spacers SW3 are formed on the side surfaces (side walls) of the gate electrode GE.

For example, an insulating film (for example, a silicon oxide film) is formed on the entire main surface of the semiconductor substrate SB so as to cover the control gate electrode CG, the floating gate electrode FG, and the gate electrode GE, and then, the insulating film is etched back by the anisotropic etching. Hence, owing to the insulating film selectively remaining on the side surface of each of the control gate electrode CG, the floating gate electrode FG, and the gate electrode GE, the sidewall spacers SW1, the sidewall spacers SW2, and the sidewall spacers SW3 can be formed.

Next, as illustrated in FIG. 14 and FIG. 15, by ion implantation, the n-type semiconductor region H1, the n-type semiconductor region H2, the n-type semiconductor region H3, the n-type semiconductor region H4, and the n-type semiconductor region H5 are formed in the semiconductor substrate SB. The control gate electrode CG, the sidewall spacer SW1, the floating gate electrode FG, the sidewall spacer SW2, the gate electrode GE, and the sidewall spacer SW3 can each function as a mask for preventing ion implantation.

Accordingly, the n-type semiconductor region H4 is formed in such a manner as to be self-aligned with the sidewall spacer SW3 on the one of the side surfaces of the gate electrode GE in the p-type well PW2, and the n-type semiconductor region H5 is formed in such a manner as to be self-aligned with the sidewall spacer SW3 on the other of the side surfaces of the gate electrode GE in the p-type well PW2. The n-type semiconductor region H1 is formed in such a manner as to be self-aligned with the sidewall spacer SW1 on the one of the side surfaces of the control gate electrode CG in the p-type well PW1. The n-type semiconductor region H3 is formed in such a manner as to be self-aligned with the sidewall spacer SW2 on the one of the side surfaces of the floating gate electrode FG in the p-type well PW1. The n-type semiconductor region H2 is formed in such a manner as to be self-aligned with the sidewall spacer SW1 on the other of the side surfaces of the control gate electrode CG and with the sidewall spacer SW2 on the other of the side surfaces of the floating gate electrode FG in the p-type well PW1. The n-type semiconductor region E2 below the sidewall spacer SW1 is the n-type semiconductor region E2a, and the n-type semiconductor region E2 below the sidewall spacer SW2 is the n-type semiconductor region E2b.

As a result, the n-type semiconductor region SD1 including the n-type semiconductor region E1 and the n-type semiconductor region H1, the n-type semiconductor region SD2 including the n-type semiconductor region E2a, the n-type semiconductor region E2b, and the n-type semiconductor region H2, and the n-type semiconductor region SD3 including the n-type semiconductor region E3 and the n-type semiconductor region H3 are formed in the p-type well PW1. The n-type semiconductor region SD4 including the n-type semiconductor region E4 and the n-type semiconductor region H4 and the n-type semiconductor region SD5 including the n-type semiconductor region E5 and the n-type semiconductor region H5 are formed in the p-type well PW2.

Next, as illustrated in FIG. 16 and FIG. 17, an insulating film (silicon oxide film) BL1 is formed on the main surface of the semiconductor substrate SB so as to cover the control gate electrode CG, the floating gate electrode FG, the gate electrode GE, the sidewall spacers SW1, the sidewall spacers SW2, the sidewall spacers SW3, the n-type semiconductor region H1, the n-type semiconductor region H2, the n-type semiconductor region H3, the n-type semiconductor region H4, and the n-type semiconductor region H5 (step S1 in FIG. 3). The insulating film BL1 is made of silicon oxide and can be formed by the CVD or the like. In step S1, a thickness of the insulating film BL1 obtained at a time of forming the insulating film BL1 is referred to as a film thickness of the insulating film BL1.

Next, by photolithography, a photoresist pattern (mask layer) RP1 is formed on the insulating film BL1 (step S2 in FIG. 3).

The photoresist pattern RP1 has the floating gate electrode FG located therein, in plan view. In other words, in plan view, the floating gate electrode FG entirely overlaps with the photoresist pattern RP1. In the case of FIG. 16, the floating gate electrode FG and the sidewall spacers SW2 lie inside the photoresist pattern RP1, in plan view. The control gate electrode CG, the sidewall spacers SW1, the gate electrode GE, and the sidewall spacers SW3 do not overlap with the photoresist pattern RP1, in plan view.

Next, as illustrated in FIG. 18 and FIG. 19, with the photoresist pattern RP1 used as an etching mask, the insulating film BL1 exposed from the photoresist pattern RP1 is subjected to the isotropic etching (step S3 in FIG. 3). Through the isotropic etching step in step S3, the thickness of the insulating film BL1 exposed from the photoresist pattern RP1 decreases.

Specifically, a thickness T2 of the insulating film BL1 obtained immediately after the isotropic etching step in step S3 has been performed is smaller than a thickness T1 of the insulating film BL1 obtained immediately before the isotropic etching step in step S3 is performed. Here, the thickness T1 and the thickness T2 each correspond to the thickness of the insulating film BL1 not covered with the photoresist pattern RP1. In addition, the thickness T1 is substantially the same as the film thickness of the insulating film BL1.

However, an etching amount (etching thickness) of the insulating film BL1 in the isotropic etching step in step S3 is smaller than the thickness T1 of the insulating film BL1 obtained immediately before the isotropic etching step in step S3 is performed. Hence, although the thickness of the insulating film BL1 not covered with the photoresist pattern RP1 decreases as a result of the isotropic etching step in step S3, it does not become zero, and even if the isotropic etching step in step S3 is ended, the insulating film BL1 remains in layers. In other words, the thickness T2 is greater than zero. Accordingly, after the isotropic etching step in step S3 and before an anisotropic etching step in step S4, the control gate electrode CG, the floating gate electrode FG, the gate electrode GE, the sidewall spacers SW1, the sidewall spacers SW2, the sidewall spacers SW3, the n-type semiconductor region H1, the n-type semiconductor region H2, the n-type semiconductor region H3, the n-type semiconductor region H4, and the n-type semiconductor region H5 are covered with the insulating film BL1 and are not exposed.

The etching amount (etching thickness) of the insulating film BL1 in the isotropic etching step in step S3 means a reduced amount of the thickness of the insulating film BL1 in the isotropic etching step in step S3. That is, the etching amount (etching thickness) of the insulating film BL1 in the isotropic etching step in step S3 corresponds to a difference (T1 - T2) between the thickness T1 of the insulating film BL1 obtained immediately before the isotropic etching step in step S3 is performed and the thickness T2 of the insulating film BL1 obtained immediately after the isotropic etching step in step S3 has been performed.

Next, as illustrated in FIG. 20 and FIG. 21, with the photoresist pattern RP1 used as the etching mask, the insulating film BL1 is subjected to the anisotropic etching (step S4 in FIG. 3). Through the anisotropic etching step in step S4, the insulating film BL1 exposed from the photoresist pattern RP1 is removed, and the insulating film BL1 remains below the photoresist pattern RP1. With the insulating film BL1 remaining below the photoresist pattern RP1, the insulating film BL is formed. Planar dimensions and a planar position of the insulating film BL substantially correspond to planar dimensions and a planar position of the photoresist pattern RP1. The thickness of the insulating film BL is substantially the same as the film thickness of the insulating film BL1 in step S1.

The insulating film BL is formed so as to cover at least the floating gate electrode FG and preferably, to cover the floating gate electrode FG and the sidewall spacers SW2. The control gate electrode CG and the gate electrode GE are not covered with the insulating film BL. In plan view, the floating gate electrode FG entirely overlaps with the insulating film BL, and the control gate electrode CG and the gate electrode GE do not overlap with the insulating film BL.

Through the anisotropic etching step in step S4, the insulating film BL1 not covered with the photoresist pattern RP1, that is, in plan view, the entire insulating film BL1 not covered with the photoresist pattern RP1 is removed. As a result, by performing the anisotropic etching step in step S4, the upper surface of the control gate electrode CG, an upper surface of the gate electrode GE, the upper surface of the n-type semiconductor region H1, the upper surface of the n-type semiconductor region H2, the upper surface of the n-type semiconductor region H3, the upper surface of the n-type semiconductor region H4, and an upper surface of the n-type semiconductor region H5 are exposed.

Note that, in the case of FIG. 20, the insulating film BL overlaps with part of the upper surface of the n-type semiconductor region H2 and part of the upper surface of the n-type semiconductor region H3. In this case, the upper surface of the n-type semiconductor region H2 has a portion covered with the insulating film BL and a portion not covered with the insulating film BL, and the upper surface of the n-type semiconductor region H3 has a portion covered with the insulating film BL and a portion not covered with the insulating film BL.

As a result of removal of the insulating film BL1 which is exposed from the photoresist pattern RP1 through the isotropic etching step in step S3 and the anisotropic etching step in step S4, the insulating film BL may have steps or inclined surfaces DS formed on end portions thereof.

Next, the photoresist pattern RP1 is removed (step S5 in FIG. 3).

Next, as illustrated in FIG. 22 and FIG. 23, a metal film ME is formed on the main surface (the entire surface of the main surface) of the semiconductor substrate SB so as to cover the control gate electrode CG, the floating gate electrode FG, the gate electrode GE, the sidewall spacers SW1, the sidewall spacers SW2, the sidewall spacers SW3, the n-type semiconductor region H1, the n-type semiconductor region H2, the n-type semiconductor region H3, the n-type semiconductor region H4, the n-type semiconductor region H5, and the insulating film BL. The metal film ME is made of, for example, a cobalt film, a nickel film, or a nickel-platinum alloy film, and can be formed by sputtering or the like.

The metal film ME is in contact with the upper surface of the control gate electrode CG, the upper surface of the gate electrode GE, the upper surface of the n-type semiconductor region H1, the upper surface of the n-type semiconductor region H2, the upper surface of the n-type semiconductor region H3, the upper surface of the n-type semiconductor region H4, and the upper surface of the n-type semiconductor region H5. Since the insulating film BL is interposed between the metal film ME and the floating gate electrode FG, the metal film ME is not in contact with the floating gate electrode FG.

Next, the semiconductor substrate SB is subjected to heat treatment, thereby causing the respective upper portions of the control gate electrode CG, the gate electrode GE, the n-type semiconductor region H1, the n-type semiconductor region H2, the n-type semiconductor region H3, the n-type semiconductor region H4, and the n-type semiconductor region H5 to react with the metal film ME. As a result, as illustrated in FIG. 24 and FIG. 25, the metal silicide layer SL that is a reaction layer of silicon and metal is formed on each of the control gate electrode CG, the gate electrode GE, the n-type semiconductor region H1, the n-type semiconductor region H2, the n-type semiconductor region H3, the n-type semiconductor region H4, and the n-type semiconductor region H5. Since the insulating film BL is interposed between the metal film ME and the floating gate electrode FG, the metal film ME does not react with the floating gate electrode FG. Accordingly, the metal silicide layer SL is not formed on the floating gate electrode FG. In other words, in a state that the insulating film BL covers the floating gate electrode FG, a formation step for the metal silicide layer SL is performed, and accordingly, the metal silicide layer SL is not formed on the floating gate electrode FG.

Next, the unreacted metal film ME is removed by wet etching or the like. The state in which the unreacted metal film ME is removed is illustrated in FIG. 24 and FIG. 25. Accordingly, the metal silicide layer SL is formed by the salicide (Self Aligned Silicide) technique.

Next, as illustrated in FIG. 26 and FIG. 27, the insulating film (silicon nitride film) SN is formed on the main surface of the semiconductor substrate SB so as to cover the control gate electrode CG, the floating gate electrode FG, the gate electrode GE, the sidewall spacers SW1, the sidewall spacers SW2, the sidewall spacers SW3, the n-type semiconductor region H1, the n-type semiconductor region H2, the n-type semiconductor region H3, the n-type semiconductor region H4, the n-type semiconductor region H5, the metal silicide layer SL, and the insulating film BL. The insulating film SN is made of silicon nitride and can be formed by the CVD or the like.

The insulating film BL is interposed between the floating gate electrode FG and the insulating film SN, and accordingly, the floating gate electrode FG is not in contact with the insulating film SN. The metal silicide layer SL on the control gate electrode CG, the metal silicide layer SL on the gate electrode GE, the metal silicide layer SL on the n-type semiconductor region H1, the metal silicide layer SL on the n-type semiconductor region H2, the metal silicide layer SL on the n-type semiconductor region H3, the metal silicide layer SL on the n-type semiconductor region H4, and the metal silicide layer SL on the n-type semiconductor region H5 are in contact with the insulating film SN.

Next, the insulating film SO is formed on the insulating film SN. The thickness of the insulating film SO is greater than the thickness of the insulating film SN. The insulating film SO is made of a material different from that of the insulating film SN, and preferably, is made of silicon oxide. As the insulating film SO, a low dielectric constant film can also be used. After the insulating film SO is formed, an upper surface of the insulating film SO is planarized by the CMP (Chemical Mechanical Polishing) or the like, as needed.

As illustrated in FIG. 26 and FIG. 27, by photolithography, a photoresist pattern (mask layer) RP2 is formed on the insulating film SO.

Next, as illustrated in FIG. 28 and FIG. 29, with the photoresist pattern RP2 as an etching mask, the insulating film SO is etched to thereby form contact holes CT in the insulating film SO. At this time, the etching is performed under a condition having an etching rate of the insulating film SN lower than an etching rate of the insulating film SO. Accordingly, the contact hole CT penetrating the insulating film SO is formed, and the insulating film SN exposed in the contact hole CT functions as an etching stopper film. Hence, the contact hole CT penetrates the insulating film SO and does not penetrate the insulating film SN.

Next, as illustrated in FIG. 30 and FIG. 31, with the photoresist pattern RP2 as the etching mask, the insulating film SN exposed from the insulating film SO is etched. At this time, the etching for the insulating film SN is performed under a condition having the etching rate of the insulating film SN greater than the etching rate of the insulating film SO. Hence, the contact hole CT penetrates the insulating film SN, and accordingly, the metal silicide layer SL is exposed in the contact hole CT. As a result, the contact hole CT penetrating the insulating film SO and the insulating film SN is formed.

Next, as illustrated in FIG. 32 and FIG. 33, the conductive plug PG is formed in the contact hole CT.

For example, a barrier conductor film is formed on a bottom surface of the contact hole CT, side surfaces of the contact hole CT, and the upper surface of the insulating film SO. Next, a main conductive film made of tungsten or the like is formed on the barrier conductor film to bury the contact hole CT. Subsequently, the main conductive film and the barrier conductor film disposed outside the contact hole CT are removed by the CMP or the like. Accordingly, the plug PG can be formed.

Next, as illustrated in FIG. 32 and FIG. 33, wires M1 are formed on the insulating film SO. For example, a conductor film is formed on the insulating film SO. Subsequently, the conductor film is patterned by photolithography and etching, so that the wires M1 made of the conductor film can be formed. As the wire M1, an aluminum wire is preferable, and a wire using other metal materials, for example, a tungsten wire, can also be applied. In addition, as the wire M1, a copper wire formed by the damascene technique can also be applied.

Illustration and description regarding a step of further forming an insulating film and a wire on the wires M1 and the insulating film SO will be omitted.

### BACKGROUND OF STUDY

The present inventor has studied the non-volatile memory having the floating gate electrode. In the non-volatile memory having the floating gate electrode, by accumulating charges in the floating gate electrode, information can be stored therein. Accordingly, enhancement of charge retention characteristics of the non-volatile memory is important, and it is necessary to prevent the charges from unintentionally going out from the floating gate electrode outside the floating gate electrode.

According to the study of the present inventor, as a cause of reduction of the charge retention characteristics of the non-volatile memory, it has been found that there is a phenomenon that the charges (electrons in this case) are moved from the floating gate electrode FG through the insulating film BL to the insulating film SN. Since a hydrogen content of the silicon nitride film is greater than a hydrogen content of the silicon oxide film, the silicon nitride film has a trap site (a trap site having positive charges) therein, attributable to hydrogen. The insulating film BL made of silicon oxide is interposed between the floating gate electrode FG and the insulating film SN made of silicon nitride. Accordingly, in a case in which the thickness of the insulating film BL is small, the charges (electrons in this case) accumulated in the floating gate electrode FG pass through the insulating film BL (silicon oxide film) and move to the insulating film SN (silicon nitride film), and may be caught in the trap site in the insulating film SN. A phenomenon that the charges accumulated in the floating gate electrode FG pass through the insulating film BL and are caught in the insulating film SN is more likely to occur, as the thickness of the insulating film BL is smaller.

In order to prevent the charges accumulated in the floating gate electrode FG from passing through the insulating film BL and being caught in the insulating film SN, increasing the thickness of the insulating film BL is effective. The greater the thickness of the insulating film BL, the greater the distance between the floating gate electrode FG and the insulating film SN (silicon nitride film), and accordingly, a possibility that the charges accumulated in the floating gate electrode FG pass through the insulating film BL and are moved to the insulating film SN decreases. Hence, increasing the thickness of the insulating film BL enhances the charge retention characteristics of the non-volatile memory. However, in a case in which the thickness of the insulating film BL is increased, the manufacturing process of the semiconductor device needs more improvement and ingenuity. Otherwise, defects may occur in the semiconductor device, which has been apparent according to the study of the present inventor.

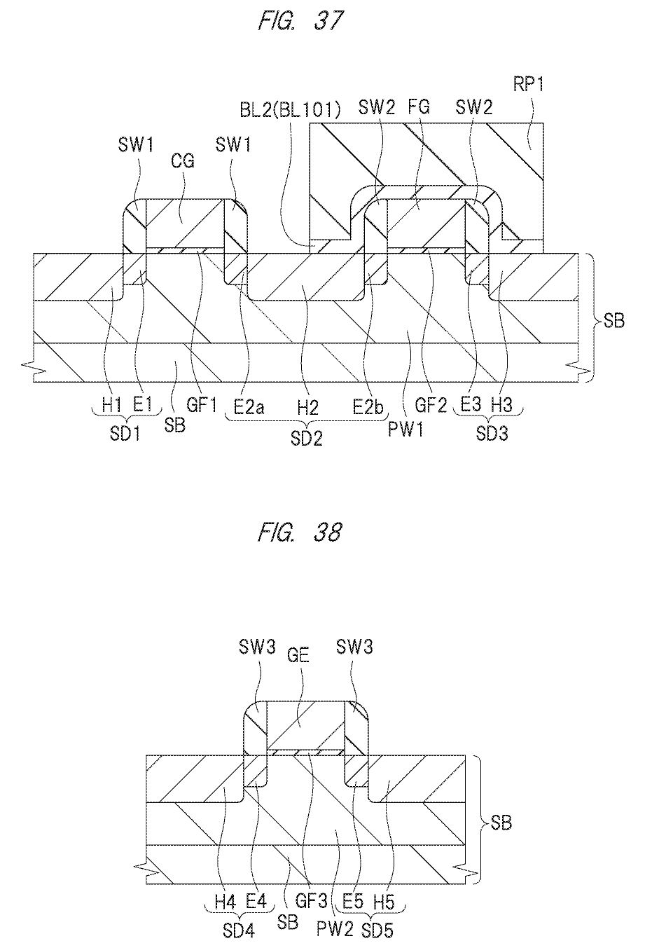

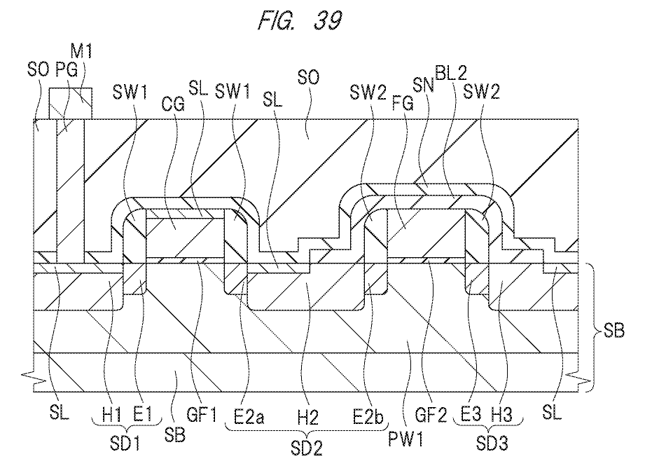

FIG. 34 is a process flow indicating part of a process of manufacturing a semiconductor device according to a first study example studied by the present inventor and corresponds to FIG. 3. FIG. 35 to FIG. 39 are cross-sectional views of main portions illustrating the manufacturing process of the semiconductor device according to the first study example studied by the present inventor. FIG. 35, FIG. 37 and FIG. 39 illustrate cross sections which correspond to FIG. 1, and FIG. 36 and FIG. 38 illustrate cross sections which correspond to FIG. 2.

As illustrated in FIG. 14 and FIG. 15, after the process of forming the n-type semiconductor region H1, the n-type semiconductor region H2, the n-type semiconductor region H3, the n-type semiconductor region H4, and the n-type semiconductor region H5, in the case of the first study example, as illustrated in FIG. 35 and FIG. 36, an insulating film BL101 corresponding to the insulating film BL1 is formed (step S101 in FIG. 34). The insulating film BL101 is formed on the main surface of the semiconductor substrate SB so as to cover the control gate electrode CG, the floating gate electrode FG, the gate electrode GE, the sidewall spacers SW1, the sidewall spacers SW2, the sidewall spacers SW3, the n-type semiconductor region H1, the n-type semiconductor region H2, the n-type semiconductor region H3, the n-type semiconductor region H4, the n-type semiconductor region H5. As with the insulating film BL1, the insulating film BL101 is made of silicon oxide, but a film thickness of the insulating film BL101 is smaller than the film thickness of the insulating film BL1.

Next, by photolithography, a photoresist pattern RP1 is formed on the insulating film BL101 (step S102 in FIG. 34).

Next, in the case of the first study example, as illustrated in FIG. 37 and FIG. 38, with the photoresist pattern RP1 used as the etching mask, the insulating film BL101 exposed from the photoresist pattern RP1 is subjected to the anisotropic etching (step S104 in FIG. 34). Specifically, in the case of the first study example, after formation of the photoresist pattern RP1 and before removal of the photoresist pattern RP1, the isotropic etching step on the insulating film BL101 is not performed, and the anisotropic etching step in step S104 is performed on the insulating film BL101.

Through the anisotropic etching step in step S104, the insulating film BL101 exposed from the photoresist pattern RP1 is removed, and the insulating film BL101 below the photoresist pattern RP1 remains. The insulating film BL101 remaining below the photoresist pattern RP1 results in formation of an insulating film BL2. The insulating film BL2 corresponds to the insulating film BL, but a thickness of the insulating film BL2 is smaller than the thickness of the insulating film BL. This is because the film thickness of the insulating film BL101 is smaller than the film thickness of the insulating film BL1. The insulating film BL2 is formed so as to cover the floating gate electrode FG and the sidewall spacers SW2. The control gate electrode CG and the gate electrode GE are not covered with the insulating film BL2.

Through the anisotropic etching step in step S104, the insulating film BL101 that is not covered with the photoresist pattern RP1 is removed, so that the upper surface of the control gate electrode CG, the upper surface of the gate electrode GE, the upper surface of the n-type semiconductor region H1, the upper surface of the n-type semiconductor region H2, the upper surface of the n-type semiconductor region H3, the upper surface of the n-type semiconductor region H4, and the upper surface of the n-type semiconductor region H5 are exposed.

Next, the photoresist pattern RP1 is removed (step S105 in FIG. 34).

Then, a formation step for the metal film ME and subsequent steps are performed. As a result, a structure of FIG. 39 corresponding to that of FIG. 32 is obtained.

In the case of the first study example, since the film thickness of the insulating film BL101 is small, the thickness of the insulating film BL2 included in the manufactured semiconductor device is also inevitably small. In a case in which the thickness of the insulating film BL2 is small, there is a concern that the charges accumulated in the floating gate electrode FG may pass through the insulating film BL2 and may be caught in the insulating film SN. Accordingly, the charge retention characteristics of the non-volatile memory may potentially be degraded.

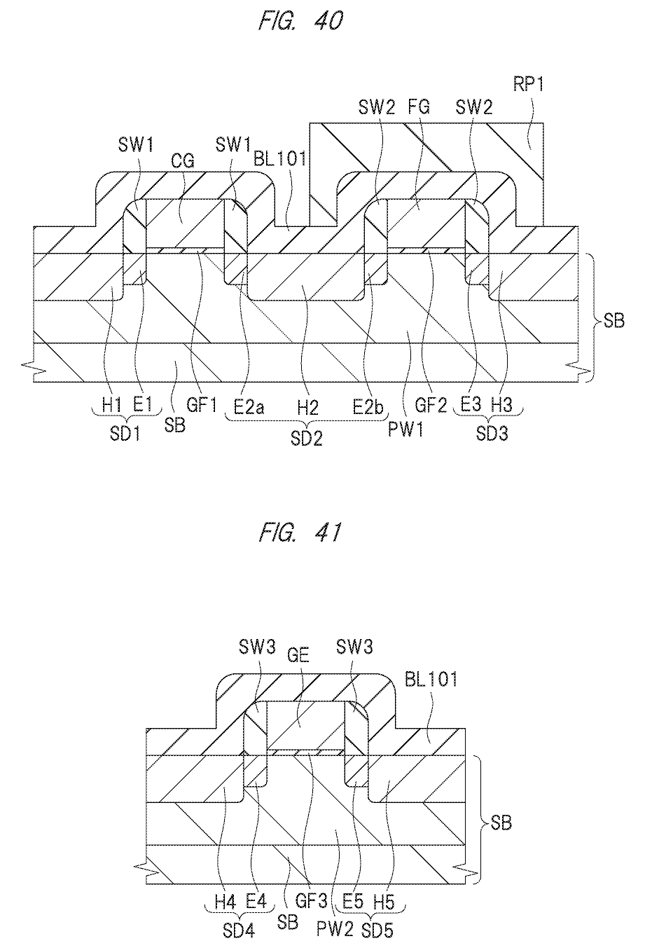

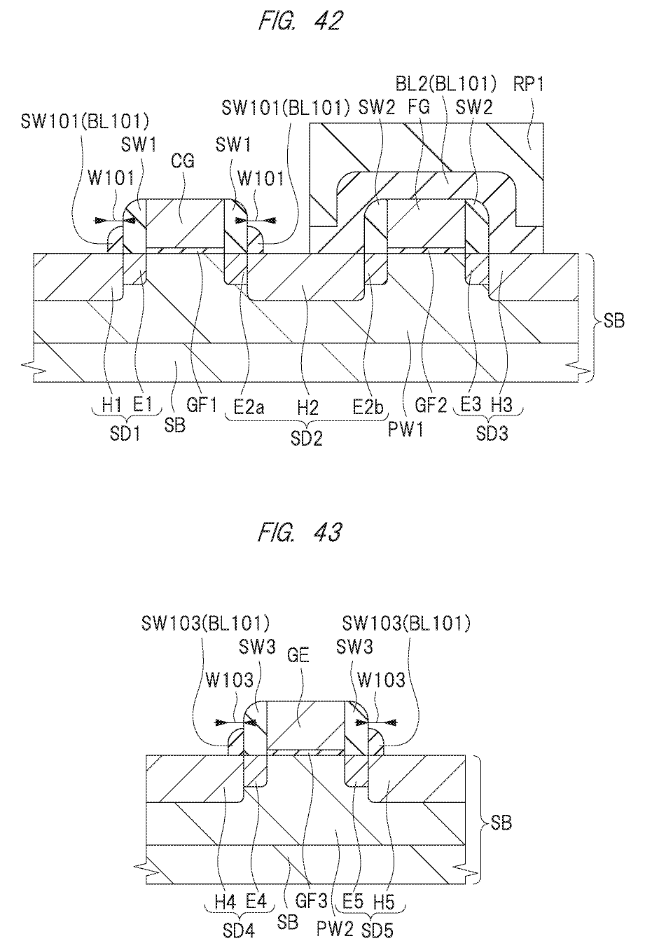

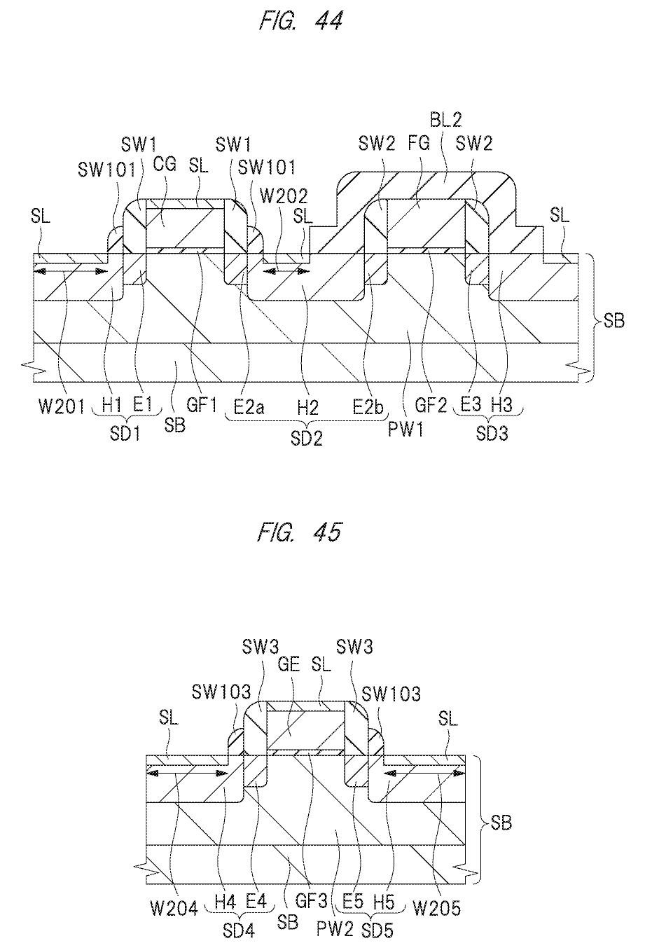

With reference to FIG. 40 through FIG. 45, a case in which a film thickness of the insulating film BL101 is increased will be described. The case in which the film thickness of the insulating film BL101 is increased will be referred to as a second study example. Also in the case of the second study example, the process flow in FIG. 34 is applied. FIG. 40, FIG. 42, and FIG. 44 illustrate cross sections which correspond to FIG. 1, and FIG. 41, FIG. 43, and FIG. 45 illustrate cross sections which correspond to FIG. 2.

As illustrated in FIG. 14 and FIG. 15, after the processes of forming the n-type semiconductor region H1, the n-type semiconductor region H2, the n-type semiconductor region H3, the n-type semiconductor region H4, and the n-type semiconductor region H5 are performed, in the case of the second study example, as illustrated in FIG. 40 and FIG. 41, the insulating film BL101 is formed (step S101 in FIG. 34). The film thickness of the insulating film BL101 in the second study example (FIG. 40 and FIG. 41) is greater than the film thickness of the insulating film BL101 in the first study example (FIG. 35 and FIG. 36). The film thickness of the insulating film BL101 in the second study example (FIG. 40 and FIG. 41) is substantially the same as the film thickness of the insulating film BL1 in the embodiment (FIG. 16 and FIG. 17).

Next, by photolithography, the photoresist pattern RP1 is formed on the insulating film BL101 (FIG. 34 in step S102).

Next, in the case of the second study example, as illustrated in FIG. 42 and FIG. 43, with the photoresist pattern RP1 used as the etching mask, the insulating film BL101 exposed from the photoresist pattern RP1 is subjected to the anisotropic etching (step S104 in FIG. 34). Specifically, in the case of the second study example, after formation of the photoresist pattern RP1 and before removal of the photoresist pattern RP1, the isotropic etching step on the insulating film BL101 is not performed, and instead, the anisotropic etching step in step S104 is performed on the insulating film BL101.

Through the anisotropic etching step in step S104, the insulating film BL101 exposed from the photoresist pattern RP1 is removed, and the insulating film BL101 remains below the photoresist pattern RP1. The insulating film BL101 remaining below the photoresist pattern RP1 results in formation of the insulating film BL2. The thickness of the insulating film BL2 illustrated in FIG. 42 (the second study example) is greater than the thickness of the insulating film BL2 illustrated in FIG. 37 (the first study example). This is because, the film thickness of the insulating film BL101 illustrated in FIG. 40 (the second study example) is greater than the film thickness of the insulating film BL101 illustrated in FIG. 35 (the first study example). The insulating film BL2 is formed so as to cover the floating gate electrode FG and the sidewall spacers SW2. The control gate electrode CG and the gate electrode GE are not covered with the insulating film BL2.

Through the anisotropic etching step in step S104, the insulating film BL101 that is not covered with the photoresist pattern RP1 is removed, and accordingly, the upper surface of the control gate electrode CG, the upper surface of the gate electrode GE, the upper surface of the n-type semiconductor region H1, the upper surface of the n-type semiconductor region H2, the upper surface of the n-type semiconductor region H3, the upper surface of the n-type semiconductor region H4, and the upper surface of the n-type semiconductor region H5 are exposed.

In the case of the second study example, when the anisotropic etching step in step S104 is ended, as illustrated in FIG. 42 and FIG. 43, the insulating film BL101 remains on the side surfaces of the sidewall spacers SW1 and side surfaces of the sidewall spacers SW3 in a sidewall spacer-like shape, so that the sidewall spacers SW101 and the sidewall spacers SW103 can be formed. The sidewall spacer SW101 (see FIG. 42) is formed by the insulating film BL101 remaining on the side surface of the sidewall spacer SW1. The sidewall spacer SW103 (see FIG. 43) is formed by the insulating film BL101 remaining on the side surface of the sidewall spacer SW3. In the case of FIG. 42, a height of the sidewall spacer SW101 is lower than a height of the sidewall spacer SW1. In the case of FIG. 43, a height of the sidewall spacer SW103 is lower than a height of the sidewall spacer SW3.

A reason that the sidewall spacers SW101 and the sidewall spacers SW103 are formed will be described below.

When the insulating film BL101 is formed in step S101, if the film thickness of the insulating film BL101 is great, the thickness of the insulating film BL101 on the side surface of the sidewall spacer SW1, the thickness of the insulating film BL101 on the side surface of the sidewall spacer SW2, and the thickness of the insulating film BL101 on the side surface of the sidewall spacer SW3 are inevitably great. When the anisotropic etching is performed on the insulating film BL101 in step S104 in a state that the thickness of the insulating film BL101 on the side surface of the sidewall spacer SW1 and the thickness of the insulating film BL101 on the side surface of the sidewall spacer SW3 are great, it is difficult to completely remove the insulating film BL101 on the side surfaces of the sidewall spacers SW1 and the insulating film BL101 on the side surfaces of the sidewall spacers SW3. Accordingly, the insulating film BL101 remaining after the anisotropic etching step in step S104 results in formation of the sidewall spacers SW101 and the sidewall spacers SW103.

If an over-etching amount through the anisotropic etching step in step S104 is made greater, it can also be considered that formation of the sidewall spacers SW101 and the sidewall spacers SW103 can be prevented. However, in a case in which the over-etching amount through the anisotropic etching step in step S104 is increased, there is a concern that the exposed semiconductor substrate SB (the n-type semiconductor region H1, the n-type semiconductor region H2, the n-type semiconductor region H3, the n-type semiconductor region H4, and the n-type semiconductor region H5) are excessively damaged due to the over-etching. Hence, to increase the over-etching amount through the anisotropic etching step in step S104 in order to prevent formation of the sidewall spacers SW101 and the sidewall spacers SW103 is not desired.

After the anisotropic etching step in step S104, the photoresist pattern RP1 is removed (step S105 in FIG. 34). Subsequently, a formation step for the metal film ME and a heat treatment step are performed, so that the metal silicide layer SL is formed, as illustrated in FIG. 44 and FIG. 45. Specifically, the metal silicide layer SL is formed by the salicide process.

In a case in which the metal silicide layer SL is formed through the salicide process in a state that the sidewall spacers SW101 are present, as illustrated in FIG. 44, the upper surface of the n-type semiconductor region H1 that is covered with the sidewall spacer SW101 and the upper surface of the n-type semiconductor region H2 that is covered with the sidewall spacer SW101 are not formed with the metal silicide layer SL. In a case in which the metal silicide layer SL is formed through the salicide process in a state that the sidewall spacers SW103 are present, as illustrated in FIG. 45, the upper surface of the n-type semiconductor region H4 that is covered with the sidewall spacer SW103 and the upper surface of the n-type semiconductor region H5 that is covered with the sidewall spacer SW103 are not formed with the metal silicide layer SL.

Accordingly, in a case in which the sidewall spacers SW101 are formed, compared to a case in which the sidewall spacer SW101 is not formed, an area of the metal silicide SL formed on the n-type semiconductor region H1 and an area of the metal silicide SL formed on the n-type semiconductor region H2 become small, and consequently, a source resistance and a drain resistance of the control transistor increase. Similarly, in a case in which the sidewall spacers SW103 are formed, compared to a case in which the sidewall spacer SW103 is not formed, an area of the metal silicide SL formed on the n-type semiconductor region H4 and an area of the metal silicide SL formed on the n-type semiconductor region H5 become small, and consequently, a source resistance and a drain resistance of the MOSFET1 increase. The increase of the source resistance and the drain resistance of the transistor causes the performance of the semiconductor device including such a transistor.

In addition, in a case in which the sidewall spacers SW101 are formed, it is difficult to accurately control the width W101 of the sidewall spacer SW101 (see FIG. 42), and the width W101 of the sidewall spacer SW101 is likely to vary. Accordingly, in a case in which the sidewall spacers SW101 are formed, the width W201 of the metal silicide SL formed on the n-type semiconductor region H1 (see FIG. 44) and the width W202 of the metal silicide SL formed on the n-type semiconductor region H2 (see FIG. 44) are likely to vary, so that the source resistance and the drain resistance of the control transistor is likely to vary. Similarly, in a case in which the sidewall spacers SW103 are formed, it is difficult to accurately control the width W103 of the sidewall spacer SW103 (see FIG. 43), and the width W103 of the sidewall spacer SW103 is likely to vary. Accordingly, in the case in which the sidewall spacers SW103 are formed, a width W204 of the metal silicide SL formed on the n-type semiconductor region H4 (see FIG. 45) and a width W205 of the metal silicide SL formed on the n-type semiconductor region H5 (see FIG. 45) are likely to vary, so that the source resistance and the drain resistance of the MOSFET1 are likely to vary. Variation in the source resistance and the drain resistance of the transistor reduces the performance of the semiconductor device including the relevant transistor. Note that the widths W101, W201, and W202 correspond to a dimension (width) along a parallel direction to the gate length direction of the control gate electrode CG. The widths W103, W204, and W205 correspond to a dimension (width) along a parallel direction to the gate length direction of the gate electrode GE.

Accordingly, in order to enhance the performance of the semiconductor device, it is desirable to prevent formation of the sidewall spacer SW101 and the sidewall spacer SW103.

In the case of the first study example illustrated in FIG. 35 to FIG. 36, the film thickness of the insulating film BL101 is small, so that formation of the sidewall spacer SW101 and the sidewall spacer SW103 can be prevented. This is because, when the insulating film BL101 is formed in step S101, if the film thickness of the insulating film BL101 is small, the thickness of the insulating film BL101 on the side surface of the sidewall spacer SW1, the thickness of the insulating film BL101 on the side surface of the sidewall spacer SW2, and the thickness of the insulating film BL101 on the side surface of the sidewall spacer SW3 also become inevitably small. When the anisotropic etching is performed on the insulating film BL101 in step S104 in a state that the thickness of the insulating film BL101 on the side surface of the sidewall spacer SW1 and the thickness of the insulating film BL101 on the side surface of the sidewall spacer SW3 are small, etching residue of the insulating film BL101 is less likely to remain on the side surface of the sidewall spacer SW1 and the side surface of the sidewall spacer SW3. As a result, it is possible to prevent formation of the sidewall spacer SW101 and the sidewall spacer SW103.

However, in a case in which the film thickness of the insulating film BL101 is small, the thickness of the insulating film BL2 included in the manufactured semiconductor device is also inevitably small, so that the charges accumulated in the floating gate electrode FG may pass through the insulating film BL2 and may be caught in the insulating film SN. Owing to this phenomenon, there is a concern that the charge retention characteristics of the non-volatile memory may be degraded.

Accordingly, in a case in which the process flow of FIG. 34 is applied, it is difficult to achieve both increasing the thickness of the insulating film BL2 and preventing formation of the sidewall spacer SW101 and the sidewall spacer SW103.

### REGARDING MAIN FEATURES AND EFFECTS

In the embodiment, the formation step for the insulating film BL includes the formation step for the insulating film BL1 in step S1, the formation step for the photoresist pattern RP1 in step S2, the isotropic etching step for the insulating film BL1 in step S3, the anisotropic etching step for the insulating film BL1 in step S4, and the removing step for the photoresist pattern RP1 in step S5. Accordingly, it is possible to achieve both increasing the thickness of the insulating film BL1 and preventing the formation of the sidewall spacer SW101 and the sidewall spacer SW103. A more detailed description regarding this will be given below.

If the film thickness of the insulating film BL1 in step S1 is great, the thickness of the insulating film BL1 on the side surface of the sidewall spacer SW1, the thickness of the insulating film BL1 on the side surface of the sidewall spacer SW2, and the thickness of the insulating film BL1 on the side surface of the sidewall spacer SW3 become inevitably great. In step S3, the insulating film BL1 exposed from the photoresist pattern RP1 is subjected to the isotropic etching, causing the thickness of the insulating film BL1 exposed from the photoresist pattern RP1 to be decreased. Step S3 is performed in a state that the insulating film BL1 on the side surface of the sidewall spacer SW1 and the insulating film BL1 on the side surface of the sidewall spacer SW3 are exposed from the photoresist pattern RP1. Hence, Through the isotropic etching step in step S3, the thickness of the insulating film BL1 on the side surface of the sidewall spacer SW1 and the thickness of the insulating film BL1 on the side surface of the sidewall spacer SW3 are decreased.

Note that, in step S3, the decrease in the thickness of the insulating film BL1 on the side surface of the sidewall spacer SW1 and the thickness of the insulating film BL1 on the side surface of the sidewall spacer SW3 can be achieved due to not the anisotropic etching, but the isotropic etching performed in step S3. It is difficult to decrease the thickness of the insulating film BL1 on the side surface of the sidewall spacer SW1 and the thickness of the insulating film BL1 on the side surface of the sidewall spacer SW3 through the anisotropic etching.

After the isotropic etching step in step S3, the anisotropic etching step in step S4 is performed. Hence, even if the film thickness of the insulating film BL1 in step S1 is great, the thickness of the insulating film BL1 on the side surface of the sidewall spacer SW1 and the thickness of the insulating film BL1 on the side surface of the sidewall spacer SW3 can be decreased through the isotropic etching in step S3, and then, the anisotropic etching step in step S4 is performed. In a state that the thickness of the insulating film BL1 on the side surface of the sidewall spacer SW1 and the thickness of the insulating film BL1 on the side surface of the sidewall spacer SW3 are small, the anisotropic etching can be performed on the insulating film BL1 in step S4, so that, when step S4 is ended, etching residue of the insulating film BL1 is less likely to remain on the side surface of the sidewall spacer SW1 and on the side surface of the sidewall spacer SW3. Hence, it is possible to prevent formation of the sidewall spacer SW101 attributable to the etching residue of the insulating film BL1 on the side surface of the sidewall spacer SW1. In addition, it is possible to prevent formation of the sidewall spacer SW103 attributable to the etching residue of the insulating film BL1 on the side surface of the sidewall spacer SW3.

In the embodiment, after the formation step for the insulating film BL1 in step S1 and the formation step for the photoresist pattern RP1 in step S2 are performed and before the anisotropic etching step in step S4 is performed, the isotropic etching step in step S3 is performed, resulting in decrease of the thickness of the insulating film BL1 on the side surface of the sidewall spacer SW1 and the thickness of the insulating film BL1 on the side surface of the sidewall spacer SW3. Owing to this decrease, even if the film thickness of the insulating film BL1 is greater in step S1, when step S4 is ended, it is possible to prevent the formation of the sidewall spacer SW101 on the side surface of the sidewall spacer SW1 and the formation of the sidewall spacer SW103 on the side surface of the sidewall spacer SW3. As a result, it is possible to achieve both increasing the thickness of the insulating film BL1 and forming the sidewall spacer SW101 and the sidewall spacer SW103.

Accordingly, in the embodiment, the film thickness of the insulating film BL1 in step S1 can be increased, so that, in the manufactured semiconductor device, such a phenomenon that the charges (electrons in this case) accumulated in the floating gate electrode FG pass through the insulating film BL and are caught in the insulating film SN can be suppressed or prevented. Accordingly, it is possible to enhance the charge retention characteristics of the non-volatile memory. Accordingly, the performance of the semiconductor device including the non-volatile memory can be enhanced.

In addition, in the embodiment, formation of the sidewall spacers SW101 can be prevented, so that it is possible to prevent decrease of the area of the metal silicide SL formed on the n-type semiconductor region H1 and the area of the metal silicide SL formed on the n-type semiconductor region H2, attributable to the presence of the sidewall spacers SW101. As a result, the source resistance and the drain resistance of the control transistor can be prevented. In addition, since formation of the sidewall spacers SW101 can be prevented, it is possible to prevent variation of the width W1 of the metal silicide SL (see FIG. 24) formed on the n-type semiconductor region H1 and the width W2 of the metal silicide SL (see FIG. 24) formed on the n-type semiconductor region H2, attributable to the presence of the sidewall spacers SW101. As a result, variation of the source resistance and the drain resistance of the control transistor can be suppressed or prevented. Accordingly, performance of the semiconductor device including the non-volatile memory can be enhanced.

In addition, in the embodiment, since formation of the sidewall spacers SW103 can be prevented, decrease of the area of the metal silicide SL formed on the n-type semiconductor region H4 and the area of the metal silicide SL formed on the n-type semiconductor region H5 which are attributable to the presence of the sidewall spacers SW103 can be prevented. As a result, the source resistance and the drain resistance of the MOSFET1 can be prevented. In addition, since formation of the sidewall spacers SW103 can be prevented, variation of the width W4 of the metal silicide SL (see FIG. 25) formed on the n-type semiconductor region H4 and the width W5 of the metal silicide SL (see FIG. 25) formed on the n-type semiconductor region H5 which are attributable to the presence of the sidewall spacers SW103 can be prevented. As a result, variation of the source resistance and the drain resistance of the MOSFET1 can be suppressed or prevented. Accordingly, performance of the semiconductor device including the non-volatile memory and the peripheral circuits can be enhanced.

The film thickness of the insulating film BL1 in step S1 is preferably equal to or greater than 70 nm. As such, the thickness of the insulating film BL between the insulating film SN and the floating gate electrode FG can be increased (70 nm or more), so that such a phenomenon that the charges accumulated in the floating gate electrode FG (electrons in this case) pass through the insulating film BL and are caught in the insulating film SN can accurately be suppressed or prevented. Accordingly, the charge retention characteristics of the non-volatile memory can accurately be enhanced.

The etching amount (etching thickness) of the insulating film BL1 in the isotropic etching step in step S3 is preferably equal to or greater than 20% of the film thickness of the insulating film BL1 in step S1. For example, in a case in which the film thickness of insulating film BL1 in step S1 is 100 nm, the etching amount of the insulating film BL1 in the isotropic etching step in step S3 is preferably equal to or greater than 20 nm. Accordingly, through the isotropic etching step in step S3, the thickness of the insulating film BL1 on the side surface of the sidewall spacer SW1 and the thickness of the insulating film BL1 on the side surface of the sidewall spacer SW3 can accurately be decreased. Hence, when the anisotropic etching step in step S4 is ended, formation of the sidewall spacer SW101 on the side surface of the sidewall spacer SW1 and the sidewall spacer SW103 on the side surface of the sidewall spacer SW3 is likely to be prevented.

Here, in the second study example above, in place of the anisotropic etching step in step S104, a case in which the isotropic etching step is performed is assumed. In this case, the insulating film BL101 exposed from the photoresist pattern RP1 is removed by the isotropic etching only. In this case, an amount by which the insulating film BL101 exposed from the photoresist pattern RP1 is isotopically etched increases, and accordingly, there is a concern that the width of the sidewall spacer SW1 becomes smaller than a desired value.

In the embodiment, the insulating film BL1 exposed from the photoresist pattern RP1 is removed by the isotropic etching step in step S3 and the anisotropic etching step in step S4. Hence, such a defect that the width of the sidewall spacer SW1 becomes smaller than a desired value, which is attributable to the increase of the amount by which the insulating film BL1 exposed from the photoresist pattern RP1 is isotopically etched, can be prevented.

Accordingly, the etching amount of the insulating film BL1 in the isotropic etching step in step S3 is preferably equal to or greater than 20% and equal to or less than 70% of the film thickness of the insulating film BL1 in step S1. For example, in a case in which the film thickness of the insulating film BL1 in step S1 is 100 nm, the etching amount of the insulating film BL1 in the isotropic etching step in step S3 is preferably equal to or greater than 20 nm and equal to or less than 70 nm. Hence, such a defect that the width of the sidewall spacer SW1 becomes less than a desired value, which is attributable to the increase of the amount by which the relevant insulating film BL1 is isotopically etched, is likely to be prevented.

In addition, in the anisotropic etching step in step S4, it is preferable that the insulating film BL1 does not remain on the side surface of the sidewall spacer SW1 and the side surface of the sidewall spacer SW3. Specifically, at a time of the end of the anisotropic etching step in step S4, it is preferable that the sidewall spacer SW101 is not formed on the side surface of the sidewall spacer SW1, and it is preferable that the sidewall spacer SW103 is not formed on the side surface of the sidewall spacer SW3. Accordingly, it is possible to accurately prevent the above-mentioned defect caused by the presence of the sidewall spacer SW101 and the above-mentioned defect caused by the presence of the sidewall spacer SW103. Hence, at the time of the end of the anisotropic etching step in step S4, in such a manner that the insulating film BL1 does not remain on the side surface of the sidewall spacer SW1 and the side surface of the sidewall spacer SW3, it is preferable to set the etching amount of the insulating film BL1 in the isotropic etching step in step S3.

However, in the anisotropic etching step in step S4, part of the insulating film BL1 may also remain on the side surface of the sidewall spacer SW1 and on the side surface of the sidewall spacer SW3. Specifically, at the time of the end of the anisotropic etching step in step S4, the sidewall spacer SW101 may be formed on the side surface of the sidewall spacer SW1, and the sidewall spacer SW103 may be formed on the side surface of the sidewall spacer SW3. However, compared to the case in which the isotropic etching in step S3 is not performed, in a case in which the isotropic etching in step S3 is performed, the width W101 of the sidewall spacer SW101 and the width W103 of the sidewall spacer SW103 formed in step S4 can be decreased. Accordingly, compared to the case in which the isotropic etching in step S3 is not performed, in the case in which the isotropic etching in step S3 is performed, it is possible to prevent the defect caused by the presence of the sidewall spacer SW101 and the defect caused by the presence of the sidewall spacer SW103.

Note that, at the time of the end of the anisotropic etching step in step S4, in a case in which the sidewall spacer SW101 is formed on the side surface of the sidewall spacer SW1, the width W101 of the sidewall spacer SW101 (specifically, the width of the insulating film BL1 remaining on the side surface of the sidewall spacer SW1) is preferably equal to or less than 10 nm. At the time of the end of the anisotropic etching step in step S4, in a case in which the sidewall spacer SW103 is formed on the side surface of the sidewall spacer SW3, the width W103 of the sidewall spacer SW103 (specifically, the width of the insulating film BL1 remaining on the side surface of the sidewall spacer SW3) is preferably equal to or less than 10 nm. Specifically, the etching amount of the insulating film BL1 in the isotropic etching step in step S3 is preferably set in such a manner that the width W101 of the sidewall spacer SW101 and the width W103 of the sidewall spacer SW103 which are formed in step S4 are equal to or less than 10 nm. Hence, the defect caused by the presence of the sidewall spacer SW101 and the defect caused by the presence of the sidewall spacer SW103 are likely to be suppressed.

In the foregoing, the invention made by the inventor of the present invention has been concretely described based on the embodiments. However, it is needless to say that the present invention is not limited to the foregoing embodiments and various modifications and alterations can be made within the scope of the present invention.

What is claimed is:

1. A method of manufacturing a semiconductor device, comprising:
(a) preparing a semiconductor substrate having a main surface;
(b) forming a floating gate electrode of a first transistor for storage on the main surface of the semiconductor substrate via a first gate insulating film, and forming a gate electrode of a second transistor on the main surface of the semiconductor substrate via a second gate insulating film;
(c) forming a first sidewall spacer on a side surface of the floating gate electrode, and forming a second sidewall spacer on a side surface of the gate electrode;
(d) forming a first semiconductor region of the first transistor and a second semiconductor region of the second transistor in the semiconductor substrate, the first semiconductor region of the first transistor being for source or drain, and the second semiconductor region of the second transistor being for source or drain;
(e) after the (c) and the (d), forming a silicon oxide film on the main surface of the semiconductor substrate so as to cover the floating gate electrode, the gate electrode, the first sidewall spacer, and the second sidewall spacer;
(f) forming a mask layer on the silicon oxide film;
(g) performing an isotropic etching on the silicon oxide film with the mask layer used as an etching mask;
(h) after the (g), performing an anisotropic etching on the silicon oxide film with the mask layer used as the etching mask;
(i) after the (h), removing the mask layer;
(j) after the (i), forming a metal silicide layer on each of the second semiconductor region and the gate electrode; and
(k) after the (j), forming a silicon nitride film on the main surface of the semiconductor substrate so as to cover the floating gate electrode, the gate electrode, the first sidewall spacer, and the second sidewall spacer,
wherein, in the (h), the silicon oxide film exposed from the mask layer is removed by the anisotropic etching, and a first insulating film made of the silicon oxide film which remains below the mask layer is formed,
wherein the first insulating film covers the floating gate electrode, and
wherein, in the (k), the first insulating film is interposed between the floating gate electrode and the silicon nitride film.

2. The method of manufacturing the semiconductor device according to claim 1,
wherein the (j) is performed in a state that the first insulating film covers the floating gate electrode, and
wherein, in the (j), no metal silicide layer is formed on the floating gate electrode.

3. The method of manufacturing the semiconductor device according to claim 1, further comprising:
(l) after the (k), forming a second insulating film on the silicon nitride film;
(m) forming a contact hole penetrating the second insulating film and the silicon nitride film; and
(n) after the (m), forming a conductive plug in the contact hole.

4. The method of manufacturing the semiconductor device according to claim 3,
wherein the second insulating film is made of a material different from that of the silicon nitride film.

5. The method of manufacturing the semiconductor device according to claim 4,
wherein the second insulating film is a silicon oxide film or a low dielectric constant film.

6. The method of manufacturing the semiconductor device according to claim 1,
wherein a film thickness of the silicon oxide film in the (e) is equal to or greater than 70 nm.

7. The method of manufacturing the semiconductor device according to claim 6,
wherein an etching thickness of the silicon oxide film in the (g) is equal to or greater than 20% of the film thickness of the silicon oxide film in the (e).

8. The method of manufacturing the semiconductor device according to claim 6,
wherein, in the (h), the silicon oxide film does not remain on a side surface of the second sidewall spacer.

9. The method of manufacturing the semiconductor device according to claim 6,
wherein, in the (h), a width of the silicon oxide film remaining on a side surface of the second sidewall spacer in a first direction is equal to or less than 10 nm, and
wherein the first direction is parallel to a gate length direction of the gate electrode.

10. The method of manufacturing the semiconductor device according to claim 1,
wherein the (j) includes
(j1) forming a metal film on the main surface of the semiconductor substrate so as to cover the floating gate electrode, the gate electrode, the first sidewall spacer, the second sidewall spacer, the first semiconductor region, the second semiconductor region, and the first insulating film,
(j2) causing the metal film to react with the second semiconductor region and the gate electrode by a heat treatment, thereby forming the metal silicide layer on the second semiconductor region and the gate electrode, and
(j3) after the (j2), removing the metal film,
wherein, in the (j1), the metal film is in contact with the second semiconductor region and the gate electrode, and the first insulating film is interposed between the metal film and the floating gate electrode.

11. The method of manufacturing the semiconductor device according to claim 1,
wherein the first insulating film covers the floating gate electrode and the first sidewall spacer.

12. The method of manufacturing the semiconductor device according to claim 1,
wherein the first insulating film covers part of the first semiconductor region, the floating gate electrode, and the first sidewall spacer, and
wherein, in the (j), the metal silicide layer is formed on the first semiconductor region that is not covered with the first insulating film.

13. The method of manufacturing the semiconductor device according to claim 1,
wherein the first transistor stores information due to accumulation of charges in the floating gate electrode.

14. The method of manufacturing the semiconductor device according to claim 13,
wherein the charges are electrons.
